(19) United States
(12) Patent Application Publication
(10) Pub. No.: US 2025/0220960 A1
(43) Pub. Date: Jul. 3, 2025

(54) SEMICONDUCTOR DEVICE

(71) Applicant: SAMSUNGELECTRONICSCO.,LTD., Suwon-si (KR)

(72) Inventors: Dongwoo KIM, Suwon-si (KR); PANKWI PARK, Suwon-si (KR); DONGSUK SHIN, Suwon-si (KR); YOUNGDAE CHO, Suwon-si (KR); RYONG HA, Suwon-si (KR)

(73) Assignee: SAMSUNGELECTRONICSCO.,LTD., Suwon-si (KR)

(21) Appl. No.: 18/751,776

(22) Filed: Jun. 24, 2024

(30) Foreign Application Priority Data
Jan. 3, 2024 (KR) 10-2024-0001169

(51) Int. Cl. H01L 29/417; H01L 21/02; H01L 23/528; H01L 29/06; H01L 29/08; H01L 29/161; H01L 29/40; H01L 29/423; H01L 29/66; H01L 29/775; H01L 29/786

(52) U.S. Cl. CPC H10D 30/6729; H01L 21/02532; H01L 23/5286; H10D 30/014; H10D 30/43; H10D 30/6735; H10D 30/6757; H10D 62/121; H10D 62/151; H10D 62/832; H10D 64/01; H10D 64/017

(57) ABSTRACT

A semiconductor device is provided. The semiconductor device includes: a substrate; a channel pattern; a source/drain pattern on the substrate; a lower wire structure body on a bottom side of the substrate; a through via penetrating the substrate and connected between the source/drain pattern and the lower wire structure body; and a landing pad between the through via and the source/drain pattern. A first element is doped to the source/drain pattern and the landing pad, such that concentration of the first element in the landing pad is equal to or greater than concentration of the first element in the source/drain pattern.

### CROSS-REFERENCE TO RELATED APPLICATION

This application claims priority to Korean Patent Application No. 10-2024-0001169, filed in the Korean Intellectual Property Office on Jan. 3, 2024, the disclosure of which is incorporated by reference herein in its entirety.

### BACKGROUND

### 1. Field

The present disclosure relates to a semiconductor device.

### 2. Description of Related Art

A semiconductor material is a material belonging to the intermediate region between a conductor and an insulator, and may conduct electricity under certain conditions. Various semiconductor devices may be manufactured using semiconductor materials, including, for example, memory devices. The semiconductor device may be implemented in various types of electronic devices.

There is a need for high reliability, high speed, and/or multifunctionality of the semiconductor devices. To satisfy these requirements, structures in the semiconductor devices are gradually becoming complicated and integrated.

### SUMMARY

One or more embodiments provide a semiconductor device with improved reliability.

An embodiment provides a semiconductor device including: a substrate; a channel pattern; a source/drain pattern on the substrate; a lower wire structure body on a bottom side of the substrate; a through via penetrating the substrate and connected between the source/drain pattern and the lower wire structure body; and a landing pad between the through via and the source/drain pattern. A first element is doped to the source/drain pattern and the landing pad, such that concentration of the first element in the landing pad is equal to or greater than concentration of the first element in the source/drain pattern.

Another embodiment provides semiconductor device including: a substrate; a channel pattern on the substrate extending in one direction; a source/drain pattern contacting a side of the channel pattern, and including a first source/drain pattern and a second source/drain pattern on the first source/drain pattern; a lower wire structure body on a bottom side of the substrate; a through via penetrating the substrate and connected between the first source/drain pattern and the lower wire structure body; and a landing pad between the through via and the first source/drain pattern. A first element is doped to the first source/drain pattern and the landing pad, such that concentration of the first element in the landing pad is greater than concentration of the first element in the first source/drain pattern. A maximum width of the landing pad in the one direction is smaller than a maximum width of the source/drain pattern in the one direction.

Another embodiment provides semiconductor device including: a substrate; a channel pattern on the substrate extending in one direction; a source/drain pattern contacting a side of the channel pattern, and including a first source/drain pattern and a second source/drain pattern on the first source/drain pattern; a lower wire structure body on a bottom side of the substrate; a through via penetrating the substrate and connected between the first source/drain pattern and the lower wire structure body; and a landing pad, to which boron is doped, protruding toward a bottom side of the substrate from a bottom side of the first source/drain pattern. A width of the landing pad increases as a distance from the bottom side of the substrate increases.

According to embodiments, reliability of the semiconductor device may be obtained.

### BRIEF DESCRIPTION OF DRAWINGS

The above and other aspects and features will be more apparent from the following description of embodiments with reference to the attached drawings, in which:

FIG. 1 shows a top plan view of a semiconductor device according to an embodiment.

FIG. 2 shows a cross-sectional view of a semiconductor device according to an embodiment.

FIG. 3 shows a cross-sectional view of a semiconductor device according to an embodiment.

FIG. 4 shows a cross-sectional view of a semiconductor device according to an embodiment.

FIG. 5 shows an enlarged cross-sectional view of a semiconductor device according to an embodiment.

FIG. 6 to FIG. 9 show cross-sectional views of a semiconductor device according to several embodiments.

FIG. 10 and FIG. 11 show cross-sectional views of a semiconductor device according to several embodiments.

FIG. 12 to FIG. 38 show cross-sectional views of intermediate stages of a method for manufacturing a semiconductor device according to an embodiment.

### DETAILED DESCRIPTION

Embodiments will be described more fully hereinafter with reference to the accompanying drawings, in which embodiments of the disclosure are shown. Each embodiment provided in the following description is not excluded from being associated with one or more features of another example or another embodiment also provided herein or not provided herein but consistent with the present disclosure. As those skilled in the art would realize, the described embodiments may be modified in various different ways, all without departing from the spirit or scope of the present disclosure.

The drawings and description are to be regarded as illustrative in nature and not restrictive, and like reference numerals designate like elements throughout the specification.

The size and thickness of each configuration shown in the drawings are shown for better understanding and ease of description, but embodiments are not limited thereto. In the drawings, the thickness of layers, films, panels, regions, areas, etc., may be enlarged for clarity and convenience of description.

It will be understood that when an element such as a layer, film, region, or substrate is referred to as being “on” another element, it can be directly on the other element or intervening elements may also be present. In contrast, when an element is referred to as being “directly on” another element, there are no intervening elements present. The word “on” or “above” means positioned on or below the object portion, and does not necessarily mean positioned “on” or “above” the upper side of the object portion based on a gravitational direction.

Unless explicitly described to the contrary, the word “comprise”, and variations such as “comprises” or “comprising”, will be understood to imply the inclusion of stated elements but not the exclusion of any other elements.

The phrase “on a plane” means viewing the object portion from the top, and the phrase “on a cross-section” means viewing a cross-section of which the object portion is perpendicularly cut from the side.

The drawing of the semiconductor device according to an embodiment may have a gate all around (GAA) in which four sides of a channel are surrounded by a gate electrode or a multi bridge channel field effect transistor (MBCFET™) structure. However, without being limited thereto, the transistor may have a fin field effect transistor (FinFET) structure, a 3D stack field effect transistor (3DSFET) structure to which the next generation is applied, or a complementary field effect transistor (CFET) structure.

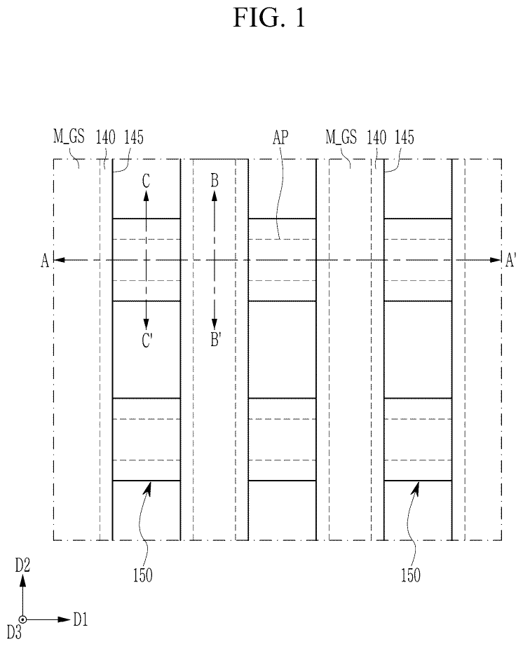

A semiconductor device according to an embodiment will now be described with reference to FIG. 1 to FIG. 5.

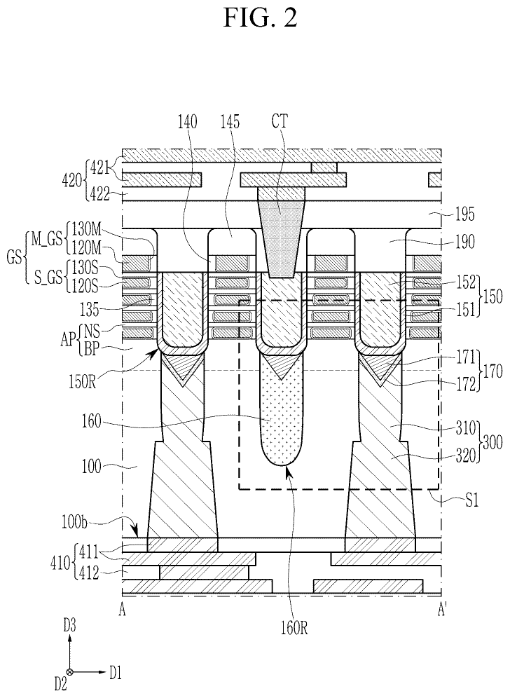

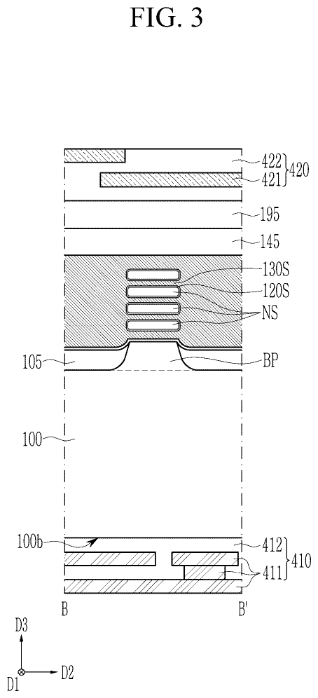

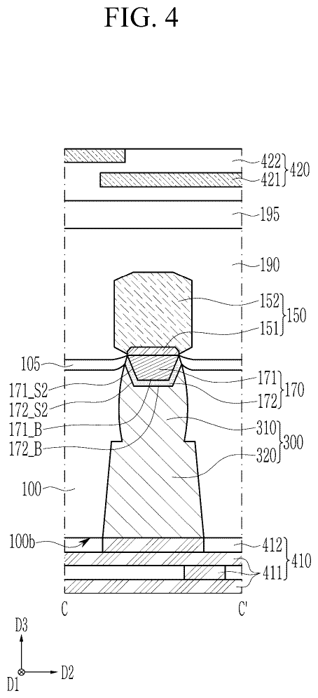

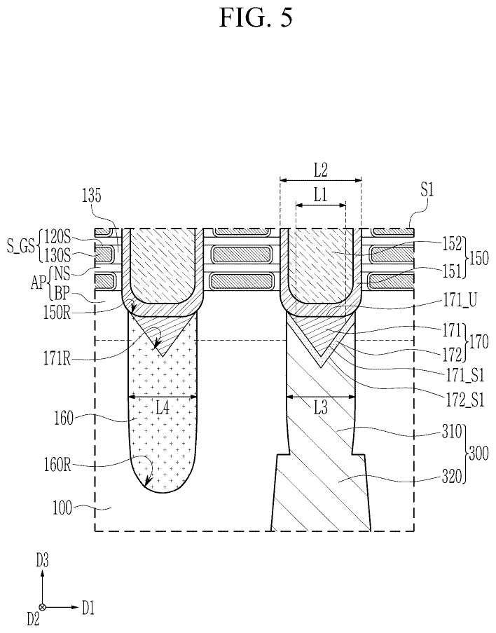

FIG. 1 shows a top plan view of a semiconductor device according to an embodiment. FIG. 2 shows a cross-sectional view with respect to a line A-A′ of FIG. 1. FIG. 3 shows a cross-sectional view with respect to a line B-B′ of FIG. 1. FIG. 4 shows a cross-sectional view with respect to a line C-C′ of FIG. 1. FIG. 5 shows an enlarged cross-sectional view of a region S1 of FIG. 2.

Referring to FIG. 1 to FIG. 4, the semiconductor device may include a substrate 100, an active pattern AP disposed on the substrate 100, a gate structure body GS disposed on the active pattern AP, source/drain patterns 150 disposed on respective sides of the active pattern AP, dummy source/drain patterns 160 disposed below the source/drain patterns 150, a lower wire structure body 410 disposed on a bottom side of the substrate 100, a through via 300 connected between the source/drain patterns 150 and the lower wire structure body 410, and a landing pad structure 170 disposed between the through via 300 and the source/drain patterns 150.

The substrate 100 may be a silicon-on-insulator (SOI) or bulk silicon. Differing from this, the substrate 100 may be a silicon substrate or may include other materials, for example, silicon germanium (SiGe), silicon germanium on insulator (SGOI), an indium antimonide, a lead telluride compound, indium arsenic, indium phosphide, gallium arsenic, or a gallium antimonide, but is not limited thereto. For another example, the substrate 100 may be an insulating substrate including an insulating material.

The substrate 100 may include a first surface and a second surface 100b. The first surface and the second surface 100b of the substrate 100 may extend along planes in parallel to a first direction D1 and a second direction D2 crossing the first direction D1. The first surface of the substrate 100 may be opposite to the second surface 100b of the substrate 100 in a third direction D3. The first surface of the substrate 100 may be referred to as an upper side or a front side of the substrate 100. The second surface 100b of the substrate 100 may be referred to a bottom side or a back side of the substrate 100. In several embodiments, a logic circuit of a cell region may be realized on the first surface of the substrate 100.

The active pattern AP may be disposed on the substrate 100. The active pattern AP may extend in the first direction D1. For example, the active pattern AP may be disposed in a region in which a PMOS is formed. For another example, the active pattern AP may be disposed in a region in which an NMOS is formed.

The active pattern AP may be a multi-channel active pattern. The active pattern AP may include a bottom pattern BP and channel patterns NS. In an embodiment, the bottom pattern BP and the channel patterns NS may have nanosheet shapes and may be semiconductor patterns including semiconductor materials. The bottom pattern BP may be disposed on the substrate 100. The bottom pattern BP may extend in the first direction D1.

The channel patterns NS may be disposed on an upper side of the bottom pattern BP. The channel patterns NS may be spaced apart from the bottom pattern BP in the third direction D3. The channel patterns NS may be spaced in the third direction D3. Here, the third direction D3 may cross the first direction D1 and the second direction D2. For example, the third direction D3 may be a thickness direction of the substrate 100. The second direction D2 may cross the first direction D1.

FIG. 2 and FIG. 3 show that four channel patterns NS are spaced and stacked in the third direction D3, which is for better understanding and ease of description and is not limited thereto. For example, three channel patterns NS may be spaced and stacked in the third direction D3.

The bottom pattern BP may be formed by etching a portion of the substrate 100, or may include an epitaxial layer grown from the substrate 100. The bottom pattern BP may include silicon (Si) or germanium (Ge) that is an elemental semiconductor material. The bottom pattern BP may include a compound semiconductor, for example, it may include a Group IV-IV compound semiconductor or a Group III-V compound semiconductor.

The Group IV-IV compound semiconductor may, for example, be a binary compound or a ternary compound including at least two of carbon (C), silicon (Si), germanium (Ge), and tin (Sn).

The group III-V compound semiconductor may, for example, be one of a binary compound, a ternary compound, and a quaternary compound formed by combining at least one of aluminum (Al), gallium (Ga), and indium (In) as group III elements and one of phosphorus (P), arsenic (As), and antimony (Sb) as group V elements.

The channel patterns NS may include one of silicon (Si) and silicon germanium (SiGe) that are elemental semiconductor material, the Group IV-IV compound semiconductor, and the Group III-V compound semiconductor. The respective channel patterns NS may include a same material as the bottom pattern BP, or may include a different material from the bottom pattern BP.

In an embodiment, the bottom pattern BP and the channel patterns NS may include silicon (Si). For another example, the bottom pattern BP and the channel patterns NS may include silicon germanium (SiGe). For another example, the bottom pattern BP may include silicon (Si), and the channel patterns NS may include silicon germanium (SiGe).

The semiconductor device according to an embodiment may further include a field insulating layer 105 disposed on the substrate 100. The field insulating layer 105 may be disposed on a sidewall of the bottom pattern BP. For example, the field insulating layer 105 may cover the entire sidewall of the bottom pattern BP. Hence, the field insulating layer 105 may overlap the bottom pattern BP in the third direction D3. The field insulating layer 105 may include, for example, an oxide, a nitride, an oxynitride, and combinations thereof. The field insulating layer 105 is shown to be a single layer, which is for better understanding and ease of description and is not limited thereto.

The gate structure body GS may be disposed on the substrate 100. The gate structure body GS may extend in the second direction D2. The gate structure body GS may be spaced and disposed in the first direction D1. The gate structure body GS may be disposed on the active pattern AP. The gate structure body GS may cross the active pattern AP. The gate structure body GS may respectively surround the channel patterns NS.

The gate structure body GS may include sub-gate structure bodies S_GS and a main gate structure body M_GS. The sub-gate structure bodies S_GS may be disposed between the channel patterns NS disposed in the third direction D3 and may be disposed between the bottom pattern BP and the channel pattern NS disposed on a lowest portion. The main gate structure body M_GS may be disposed on the channel pattern NS disposed on a highest portion.

In detail, the sub-gate structure bodies S_GS may be disposed between an upper side of the bottom pattern BP and a bottom side of the lowest portion channel pattern NS, and between an upper side of the channel pattern NS and a bottom side of the channel pattern NS facing each other in the third direction D3. The sub-gate structure bodies S_GS may be disposed near the source/drain patterns 150 to be described. The main gate structure body M_GS may be disposed on the sub-gate structure bodies S_GS and the channel pattern NS.

According to an embodiment, the active pattern AP may include channel patterns NS, and the gate structure body GS may include sub-gate structure bodies S_GS. The number of the sub-gate structure bodies S_GS may be proportional to the number of the channel patterns NS included in the active pattern AP. For example, the number of the sub-gate structure bodies S_GS may be equal to the number of the channel patterns NS. For example, as shown in FIG. 2 and FIG. 3, the number of the sub-gate structure bodies S_GS may be 4. However, without being limited thereto, the sub-gate structure bodies S_GS may include three or more than five sub-gate structure bodies S_GS.

The respective sub-gate structure bodies S_GS may include a sub-gate electrode 120S and a sub-gate insulating layer 130S.

The sub-gate electrode 120S may be disposed on the bottom pattern BP. The sub-gate electrode 120S may cross the bottom pattern BP. The sub-gate electrode 120S may surround the channel patterns NS. At least a portion of the sub-gate electrode 120S may be disposed on the sub-gate electrode 120S and a stacking structure of the channel patterns NS. Another portion of the sub-gate electrode 120S may cover the sub-gate electrode 120S and respective sides of the stacking structure of the channel patterns NS. Four surfaces of the channel patterns NS may be surrounded by the sub-gate electrode 120S.

The sub-gate electrode 120S may include at least one of a metal, a metal alloy, a conductive metal nitride, a metal silicide, a doped semiconductor material, a conductive metal oxide, and a conductive metal oxynitride. The sub-gate electrode 120S may, for example, include at least one of a titanium nitride (TiN), a tantalum carbide (TaC), a tantalum nitride (TaN), a titanium silicon nitride (TiSiN), a tantalum silicon nitride (TaSiN), ta antalum titanium nitride (TaTiN), a titanium aluminum nitride (TiAlN), a tantalum aluminum nitride (TaAlN), a tungsten nitride (WN), ruthenium (Ru), titanium aluminum (TiAl), a titanium aluminum carbonitride (TiAlC-N), a titanium aluminum carbide (TiAlC), a titanium carbide (TIC), a tantalum carbonitride (TaCN), tungsten (W), aluminum (Al), copper (Cu), cobalt (Co), titanium (Ti), tantalum (Ta), nickel (Ni), platinum (Pt), nickel platinum (Ni—Pt), niobium (Nb), a niobium nitride (NbN), a niobium carbide (NbC), molybdenum (Mo), a molybdenum nitride (MoN), a molybdenum carbide (MoC), a tungsten carbide (WC), rhodium (Rh), palladium (Pd), iridium (Ir), osmium (Os), silver (Ag), gold (Au), zinc (Zn), vanadium (V), and combinations thereof, and is not limited thereto. The conductive metal oxide and the conductive metal oxynitride may include the above-noted materials that are oxidized, but are not limited thereto.

The sub-gate insulating layer 130S may extend along the upper side of the bottom pattern BP. The sub-gate insulating layer 130S may be disposed along edges of the channel patterns NS. The sub-gate insulating layer 130S may contact the bottom pattern BP, the inner gate spacer 135, and the channel patterns NS. The sub-gate insulating layer 130S may be disposed between the channel patterns NS and the sub-gate electrode 120S. The sub-gate insulating layer 130S may also extend along an upper side of the field insulating layer 105. The sub-gate insulating layer 130S may include various insulating materials.

In an embodiment, the sub-gate insulating layer 130S, as shown, is a single layer, but is not limited thereto. For example, the sub-gate insulating layer 130S may include a multilayer including a silicon oxide (SiO₂) and a material with a high dielectric constant. The high dielectric material may include a material that has a greater dielectric constant than the silicon oxide (SiO₂), such as a hafnium oxide (HfO), an aluminum oxide (AlO), or a tantalum oxide (TaO).

The main gate structure body M_GS may be disposed on the sub-gate structure body S_GS and the channel patterns NS. The main gate structure body M_GS may be disposed on the upper sides of the channel patterns NS.

The main gate structure body M_GS may include a main gate electrode 120M and a main gate insulating layer 130M.

The main gate electrode 120M may be disposed on the sub-gate structure body S_GS and the channel patterns NS. The main gate electrode 120M may be disposed on the upper sides of the channel patterns NS. The main gate electrode 120M may include the same material as the sub-gate electrode 120S. For example, the main gate electrode 120M may include at least one of a metal, a metal alloy, a conductive metal nitride, a metal silicide, a doped semiconductor material, a conductive metal oxide, and a conductive metal oxynitride.

The main gate insulating layer 130M may extend along a lateral side of the main gate electrode 120M and a lower side of the main gate electrode 120M. The main gate insulating layer 130M may extend along a lateral side of a gate spacer 140. The main gate insulating layer 130M may include various insulating materials.

In an embodiment, the main gate insulating layer 130M is, as shown, a single layer, but is not limited thereto. For example, the main gate insulating layer 130M may include a multilayer including a silicon oxide (SiO₂) and a high dielectric material. The high dielectric material may include a material that has a greater dielectric constant than the silicon oxide (SiO₂), such as a hafnium oxide (HfO), an aluminum oxide (AlO), or a tantalum oxide (TaO).

The semiconductor device may further include an inner gate spacer 135, a gate spacer 140, and a capping layer 145.

The inner gate spacer 135 may be disposed on the lateral side of the sub-gate structure body S_GS. For example, the inner gate spacer 135 may be disposed between the source/drain patterns 150 and the sub-gate structure body S_GS. The inner gate spacer 135 may not be disposed on the lateral side of the main gate structure body M_GS. The semiconductor device according to several embodiments may not include the inner gate spacer 135. In this case, the sub-gate structure body S_GS may contact the source/drain patterns 150.

The gate spacer 140 may be disposed on a lateral side of the main gate electrode 120M. The gate spacer 140 may not be disposed between the bottom pattern BP and the channel patterns NS. The gate spacer 140 may not be disposed between the channel patterns NS that are disposed near in the third direction D3.

The gate spacer 140 may, for example, include at least one of a silicon nitride (SiN), a silicon oxynitride (SiON), a silicon oxide (SiO₂), a silicon oxycarbonitride (SiOCN), a silicon boron nitride (SiBN), a silicon oxyboron nitride (SiOBN), a silicon oxycarbide (SiOC), and combinations thereof. The gate spacer 140 is shown to be a single layer, which is for better understanding and ease of description and is not limited thereto.

The capping layer 145 may be disposed on the main gate structure body M_GS and the gate spacer 140. An upper side of the capping layer 145 may be disposed on the same plane as the upper side of the interlayer insulating layer 190. Differing from what is shown, an upper side of the gate spacer 140 may extend to be disposed on the same plane as the upper side of the interlayer insulating layer 190, and the capping layer 145 may be disposed between the gate spacer 140.

The capping layer 145 may, for example, include at least one of a silicon nitride (SiN), a silicon oxynitride (SiON), a silicon carbonitride (SiCN), a silicon oxycarbonitride (SiOCN), and combinations thereof. The capping layer 145 may include a material that has etching selectivity with respect to the interlayer insulating layer 190.

The source/drain patterns 150 may be disposed on respective sides of the sub-gate structure body S_GS. The source/drain patterns 150 may contact the lateral side of the channel pattern NS and the lateral side of the inner gate spacer 135. The source/drain patterns 150 may be connected to the channel pattern NS. In an embodiment, the source/drain patterns 150 may be connected to the dummy source/drain pattern 160 or the through via 300. For example, a portion of the source/drain patterns 150 may be connected to the dummy source/drain pattern 160, and another portion of the source/drain patterns 150 may be connected to the through via 300.

The source/drain patterns 150 may be disposed in a source/drain recess 150R extending in the third direction D3. The source/drain patterns 150 may fill the source/drain recess 150R. A bottom side of the source/drain recess 150R may be defined by the landing pad structure 170. A lateral side of the source/drain recess 150R may be defined by the inner gate spacer 135 and the active pattern AP.

In an embodiment, the bottom sides of the source/drain patterns 150 may be disposed lower than the bottom sides of the sub-gate structure bodies S_GS. For example, as shown in FIG. 2, the bottom sides of the source/drain patterns 150 may be disposed nearer the second surface 100b of the substrate 100 than the bottom side of the sub-gate structure body S_GS disposed on the lowest portion. In this regard, a distance from the second surface 100b of the substrate 100 to the bottom sides of the source/drain patterns 150 in the third direction D3 may be smaller than a distance from the second surface 100b of the substrate 100 to the bottom side of the sub-gate structure body S_GS disposed on the lowest portion in the third direction D3.

The source/drain patterns 150 may be epitaxial patterns formed by a selective epitaxial growth process using a landing pad 171 and the channel patterns NS as seeds. For example, the source/drain patterns 150 may be formed on an upper side of the landing pad 171 and lateral sides of the channel patterns NS. Hence, the bottom sides of the source/drain patterns 150 may have a shape complementary to the upper side of the landing pad 171. The source/drain patterns 150 may function as source/drains of the transistor using the channel pattern NS as channel regions.

The source/drain patterns 150 of the semiconductor device according to an embodiment may include a first source/drain pattern 151 and a second source/drain pattern 152.

The first source/drain pattern 151 may be formed along an inner sidewall and a bottom side of the source/drain recess 150R. The first source/drain pattern 151 formed along the inner sidewall of the source/drain recess 150R may contact the inner gate spacer 135 and the active pattern AP. The first source/drain pattern 151 may be connected to the landing pad structure 170. The first source/drain pattern 151 may be electrically connected to the through via 300 by the landing pad structure 170. The first source/drain pattern 151 may include a first material that is a semiconductor material. For example, the first source/drain pattern 151 may include silicon (Si) or germanium (Ge) that is a semiconductor material.

The second source/drain pattern 152 may be disposed on the first source/drain pattern 151. The second source/drain pattern 152 may fill a portion of the source/drain recess 150R that remains after the first source/drain pattern 151 is formed.

The second source/drain pattern 152 may include a semiconductor material. The second source/drain pattern 152 may include a first material and a second material that is different from the first material. The second material may, for example, include carbon (C), silicon (Si), germanium (Ge), and tin (Sn). For example, the first source/drain pattern 151 may include silicon (Si), and the second source/drain pattern 152 may include silicon germanium (SiGe).

However, without being limited thereto, for another example, the second source/drain pattern 152 may include the same material as the first source/drain pattern 151. Contents (at %) of materials of the second source/drain pattern 152 and the first source/drain pattern 151 may be the same or different. For example, when the second source/drain pattern 152 and the first source/drain pattern 151 include silicon germanium (SiGe), the content (at %) of the germanium (Ge) of the second source/drain pattern 152 may be greater than the content (at %) of the germanium (Ge) of the first source/drain pattern 151, but is not limited thereto. For another example, the second source/drain pattern 152 may include the same material as the first source/drain pattern 151, and the second source/drain pattern 152 and the first source/drain pattern 151 may have the contents (at %) of the same configuring material.

In an embodiment, a first element may be doped into the first source/drain pattern 151 and the second source/drain pattern 152. For example, when the semiconductor device according to an embodiment is an N-type semiconductor device, the first element may be N-type impurities. For example, the first element may include P, Sb, As, or combinations thereof. The concentration of the first element in the first source/drain pattern 151 may be different from the concentration of the first element in the second source/drain pattern 152. For example, the concentration of the first element doped to the second source/drain pattern 152 may be greater than the concentration of the first element doped to the first source/drain pattern 151. For another example, when the semiconductor device according to an embodiment is a P-type semiconductor device, the first element may be P-type impurities. For example, the first element may include B, V, In, Ga, Al, and combinations thereof. The concentration of the first element in the first source/drain pattern 151 may be different from the concentration of the first element in the second source/drain pattern 152. For example, the concentration of the first element doped to the second source/drain pattern 152 may be greater than the concentration of the first element doped to the first source/drain pattern 151.

The source/drain patterns 150 have been described as being multilayers, but embodiments are not limited thereto, and the source/drain patterns 150 may include a single layer including a semiconductor material. In another example, the source/drain patterns 150 may be formed of at least three layers including a semiconductor material.

The landing pad structure 170 may be embedded in the substrate 100. The landing pad structure 170 may be disposed on the bottom sides of the source/drain patterns 150. The landing pad structure 170 may be disposed between the source/drain patterns 150 and the through via 300. The landing pad structure 170 may be electrically connected to the source/drain patterns 150 and the through via 300. Hence, the source/drain patterns 150 may be electrically connected to the through via 300 by the landing pad structure 170.

The landing pad structure 170 may include a landing pad 171 disposed on the bottom sides of the source/drain patterns 150 and a silicide layer 172 surrounding the landing pad 171.

Referring to FIG. 5, the landing pad 171 may be disposed on the bottom side of the source/drain patterns 150. For example, the landing pad 171 may be disposed on the bottom side of the first source/drain pattern 151. The landing pad 171 may be disposed between the source/drain patterns 150 and the through via 300. The landing pad 171 may also be disposed between the source/drain patterns 150 and the dummy source/drain pattern 160. That is, at least a portion of the landing pad 171 may be disposed over the through via 300, and another portion of the landing pad 171 may be disposed on the dummy source/drain pattern 160. A landing pad recess 171R may be defined by each of the dummy source/drain pattern 160 and the through via 300. The landing pad 171 may fill the landing pad recess 171R of the dummy source/drain pattern 160. The landing pad 171 and the silicide layer 172 may fill the landing pad recess 171R of the through via 300. The landing pad 171 may be epitaxial patterns formed by a selective epitaxial growth process using the dummy source/drain pattern 160 as seeds.

The landing pad 171 may be may be spaced apart from the second source/drain pattern 152. That is, an upper side 171_U of the landing pad 171 may contact the first source/drain pattern 151, and may be may be spaced apart from the second source/drain pattern 152 by the first source/drain pattern 151. The upper side 171_U of the landing pad 171 may have a shape complementary to the bottom side of the first source/drain pattern 151. For example, the upper side 171_U of the landing pad 171 may be flat on a cross-section formed by the first direction D1 and the third direction D3. As shown in FIG. 4, the upper side of the landing pad 171 may be flat on a cross-section formed by the second direction D2 and the third direction D3. In this case, a portion of the bottom side of the first source/drain pattern 151 contacting the upper side 171_U of the landing pad 171 may be flat. However, a shape of the upper side 171_U of the landing pad 171 is not limited thereto.

In an embodiment, the landing pad 171 may protrude toward the second surface 100b of the substrate 100 from the bottom side of the first source/drain pattern 151. For example, as shown in FIG. 5, a width of the landing pad 171 in the first direction D1 may be reduced in accordance with a distance from the bottom side of the first source/drain pattern 151 on the cross-section formed by the first direction D1 and the third direction D3. That is, the width of the landing pad 171 in the first direction D1 may increase in accordance with a distance from the second surface 100b of the substrate 100. A first width L1 of the landing pad 171 in the first direction D1 may be smaller than a second width L2 of the source/drain patterns 150 in the first direction D1. The first width L1 of the landing pad 171 in the first direction D1 may represent a maximum width of the landing pad 171 in the first direction D1. A second width L2 of the source/drain patterns 150 in the first direction D1 may represent a maximum width of the source/drain patterns 150 in the first direction D1.

As shown in FIG. 4, the width of the landing pad 171 in the second direction D2 may be reduced in accordance with a distance from the bottom side of the source/drain patterns 150 on the cross-section formed by the second direction D2 and the third direction D3. That is, the width of the landing pad 171 in the second direction D2 may increase in accordance with a distance from the second surface 100b of the substrate 100. The maximum width of the landing pad 171 in the second direction D2 may be smaller than the maximum width of the source/drain patterns 150 in the second direction D2. For example, the width of the landing pad 171 in the second direction D2 may be smaller than the width of the second source/drain pattern 152 in the second direction D2.

In an embodiment, a lateral side of the landing pad 171 may include a side that inclines from the second surface 100b of the substrate 100. For example, as shown in FIG. 5, the landing pad 171 may include a first lateral side 171_S1 that inclines from the second surface 100b of the substrate 100 by a predetermined angle on the cross-section formed by the first direction D1 and the third direction D3. The first lateral side 171_S1 of the landing pad 171 may be flat, but is not limited thereto. That is, the first lateral side 171_S1 of the landing pad 171 may extend straight on the cross-section formed by the first direction D1 and the third direction D3. The first lateral side 171_S1 of the landing pad 171 may represent the lateral side of the landing pad 171 on the cross-section formed by the first direction D1 and the third direction D3.

As shown in FIG. 4, the landing pad 171 may include a second lateral side 171_S2 that inclines from the second surface 100b of the substrate 100 by a predetermined angle on the cross-section formed by the second direction D2 and the third direction D3. The second lateral side 171_S2 of the landing pad 171 may be flat, but is not limited thereto. That is, the second lateral side 171_S2 of the landing pad 171 may extend straight on the cross-section formed by the second direction D2 and the third direction D3. An angle between the second lateral side 171_S2 of the landing pad 171 and the second surface 100b of the substrate 100 may be substantially equal to an angle between the first lateral side 171_S1 of the landing pad 171 and the second surface 100b of the substrate 100, but is not limited thereto. For example, the angle between the second lateral side 171_S2 of the landing pad 171 and the second surface 100b of the substrate 100 may be different from the angle between the first lateral side 171_S1 of the landing pad 171 and the second surface 100b of the substrate 100. The second lateral side 171_S2 of the landing pad 171 may represent the lateral side of the landing pad 171 on the cross-section formed by the second direction D2 and the third direction D3.

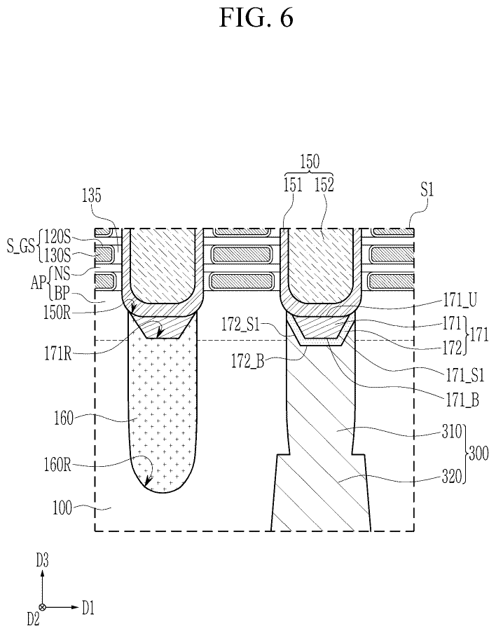

In an embodiment, the landing pad 171 may further include a bottom side 171_B extending in parallel to the second surface 100b of the substrate 100. For example, as shown in FIG. 4, the bottom side 171_B of the landing pad 171 may extend in the second direction D2 on the cross-section formed by the second direction D2 and the third direction D3. However, without being limited thereto, for example, the bottom side 171_B of the landing pad 171 may extend in the first direction D1. This will be described later with reference to FIG. 6.

The landing pad 171 may include a semiconductor material. The landing pad 171 may include the same material as the source/drain patterns 150. For example, the landing pad 171 may include a first material and a second material that is different from the first material. For example, the first material may include silicon (Si), and the second material may include germanium (Ge).

In an embodiment, when the landing pad 171 and the dummy source/drain pattern 160 include silicon germanium (SiGe), the content (at %) of germanium (Ge) of the landing pad 171 may be greater than the content (at %) of germanium (Ge) of the dummy source/drain pattern 160. For example, the content (at %) of germanium (Ge) of the landing pad 171 may be equal to or greater than about 50 at % and smaller than about 100 at %. In this range, the landing pad 171 may have etching selectivity with respect to the dummy source/drain pattern 160. Here, the content (at %) of germanium (Ge) of the landing pad 171 may represent the content (at %) of germanium (Ge) in the entire content (at %) of the landing pad 171. The content (at %) of germanium (Ge) of the dummy source/drain pattern 160 may represent the content (at %) of germanium (Ge) in the entire content (at %) of the dummy source/drain pattern 160.

For example, when the landing pad 171, the first source/drain pattern 151, and the second source/drain pattern 152 include silicon germanium (SiGe), the content (at %) of germanium (Ge) of the landing pad 171 may be equal to or greater than the content (at %) of germanium (Ge) of the source/drain patterns 150. For example, the content (at %) of germanium (Ge) of the landing pad 171 may be greater than the content (at %) of germanium (Ge) of the first source/drain pattern 151. The content (at %) of germanium (Ge) of the landing pad 171 may be equal to or greater than the content (at %) of germanium (Ge) of the second source/drain pattern 152.

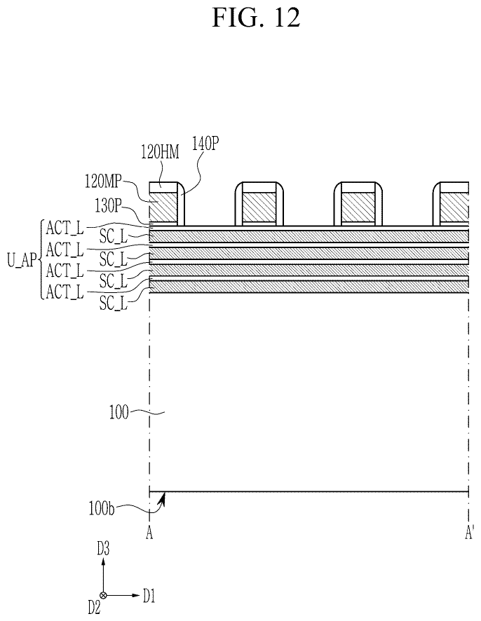

In an embodiment, impurities may be doped into the landing pad 171. For example, the landing pad 171 may include the same material as the first element doped to the source/drain patterns 150. For example, when the semiconductor device is a P-type semiconductor device, the first element may include boron (B). The concentration of the first element in the landing pad 171 may be greater than the concentration of the first element in the first source/drain pattern 151. For example, the concentration of the first element in the landing pad 171 may be about 8×10²⁰ cm⁻³ to about 5×10²¹ cm⁻³. The concentration of the first element in the landing pad 171 may be equal to or greater than the concentration of the first element in the second source/drain pattern 152. However, without being limited thereto, for another example, when the semiconductor device is an N-type semiconductor device, the first element may include boron (B), carbon (C), and combinations thereof. Hence, the landing pad 171 may have etching selectivity with respect to the dummy source/drain pattern 160. Therefore, when the landing pad 171 is exposed in a process for removing the dummy source/drain pattern 160, the landing pad 171 may not be etched. This will be described later with reference to FIG. 12.

The landing pad 171 may electrically connect the through via 300 and the source/drain patterns 150. When the landing pad 171 protrudes on the bottom side of the first source/drain pattern 151, a contact area between the landing pad 171 and the through via 300 may increase. Hence, contact resistance between the landing pad 171 and the through via 300 may be reduced to increase reliability of the semiconductor device.

The silicide layer 172 may surround the landing pad 171. For example, the silicide layer 172 may be disposed on the first lateral side 171_S1 of the landing pad 171 and the second lateral side 171_S2 of the landing pad 171. The silicide layer 172 may be disposed between the landing pad 171 and the through via 300. The silicide layer 172 may be disposed along an interface of the landing pad 171 facing the through via 300. For example, the silicide layer 172 may be disposed with a constant thickness on the first lateral side 171_S1 and the second lateral side 171_S2 of the landing pad 171. The silicide layer 172 may contact the through via 300 and the landing pad 171. The silicide layer 172 may be electrically connected to the through via 300 and the landing pad 171.

In an embodiment, a lateral side of the silicide layer 172 may include a side inclined from the second surface 100b of the substrate 100. For example, as shown in FIG. 5, the silicide layer 172 may include a first lateral side 172_S1 inclined from the second surface 100b of the substrate 100 by a predetermined angle on the cross-section formed by the first direction D1 and the third direction D3. The first lateral side 172_S1 of the silicide layer 172 may be flat, but is not limited thereto. That is, the first lateral side 172_S1 of the silicide layer 172 may extend straight on the cross-section formed by the first direction D1 and the third direction D3.

As shown in FIG. 4, the silicide layer 172 may include a second lateral side 172_S2 inclined from the second surface 100b of the substrate 100 by a predetermined angle on the cross-section formed by the second direction D2 and the third direction D3. The second lateral side 172_S2 of the silicide layer 172 may be flat, but is not limited thereto. That is, the second lateral side 172_S2 of the silicide layer 172 may extend straight on the cross-section formed by the second direction D2 and the third direction D3. The angle between the second lateral side 172_S2 of the silicide layer 172 and the second surface 100b of the substrate 100 may be substantially equal to the angle between the first lateral side 172_S1 of the silicide layer 172 and the second surface 100b of the substrate 100, but is not limited thereto. For example, the angle between the second lateral side 172_S2 of the silicide layer 172 and the second surface 100b of the substrate 100 may be different from the angle between the first lateral side 172_S1 of the silicide layer 172 and the second surface 100b of the substrate 100.

In an embodiment, the silicide layer 172 may further include a bottom side 172_B extending in parallel to the second surface 100b of the substrate 100. For example, as shown in FIG. 4, the bottom side 172_B of the silicide layer 172 may extend in the second direction D2 on the cross-section formed by the second direction D2 and the third direction D3. However, without being limited thereto, for example, the bottom side 172_B of the silicide layer 172 may extend in the first direction D1. This will be described later with reference to FIG. 6.

The silicide layer 172 may include a metal silicide. For example, the silicide layer 172 may include at least one of a titanium silicide, a tantalum silicide, a tungsten silicide, a nickel silicide, and a cobalt silicide. In several embodiments, a barrier metal layer may be disposed between the silicide layer 172 and the through via 300, but is not limited thereto.

The landing pad 171 may include may include a greater content (at %) of a second material (e.g., germanium (Ge)) than the source/drain patterns 150, and may include a higher concentration of the first element (e.g., boron (B)) than the source/drain patterns 150. Hence, Schottky barriers between the landing pad 171 and the silicide layer 172 may be reduced, and characteristics of the semiconductor device may be improved.

The dummy source/drain pattern 160 may be embedded in the substrate 100. The dummy source/drain pattern 160 may be disposed below the landing pad structure 170. The dummy source/drain pattern 160 may be disposed below at least one of the source/drain patterns 150.

The dummy source/drain pattern 160 may be disposed in the dummy source/drain recess 160R extending in the third direction D3. The dummy source/drain pattern 160 may fill the dummy source/drain recess 160R. The bottom side of the dummy source/drain pattern 160 may be defined by the substrate 100, and the lateral side of the dummy source/drain pattern 160 may be defined by the bottom pattern BP of the substrate 100.

In an embodiment, an upper side of the dummy source/drain pattern 160 may be disposed nearer the second surface 100b of the substrate 100 than the bottom side of the sub-gate structure body S_GS disposed on the lowest portion. In this regard, the distance from the second surface 100b of the substrate 100 to the upper side of the dummy source/drain pattern 160 in the third direction D3 may be smaller than the distance from the second surface 100b of the substrate 100 to the bottom side of the sub-gate structure body S_GS disposed on the lowest portion in the third direction D3.

The dummy source/drain pattern 160 may include the same material as the source/drain patterns 150. For example, the dummy source/drain pattern 160 may include a first material and a second material. The second material may be different from the first material. The second material may include, for example, carbon (C), silicon (Si), germanium (Ge), or tin (Sn).

The content (at %) of the second material of the dummy source/drain pattern 160 may be smaller than the content (at %) of the second material of the second source/drain pattern 152. For example, when the first material is silicon (Si) and the second material is germanium (Ge), the concentration of germanium (Ge) included by the dummy source/drain pattern 160 may be smaller than the concentration of germanium (Ge) included by the second source/drain pattern 152. However, without being limited thereto, the concentration of the second material of the dummy source/drain pattern 160 may be greater than the concentration of the second material of the second source/drain pattern 152. For example, when the first source/drain pattern 151 and the dummy source/drain pattern 160 include silicon germanium (SiGe), the concentration of germanium (Ge) of the dummy source/drain pattern 160 may be greater than the concentration of germanium (Ge) of the first source/drain pattern 151. FIG. 2 shows that the dummy source/drain pattern 160 is disposed between the through via 300 disposed near in the first direction D1, which is for better understanding and ease of description and is not limited thereto.

The semiconductor device may further include an interlayer insulating layer 190.

The interlayer insulating layer 190 may be disposed on a lateral side of the gate spacer 140, a lateral side of the capping layer 145, and an upper side of the source/drain patterns 150. The interlayer insulating layer 190 may not cover the upper side of the capping layer 145.

The interlayer insulating layer 190 may, for example include at least one of a silicon oxide (SiO₂), a silicon nitride (SiN), a silicon oxynitride (SiON), and a low dielectric material. The low dielectric material may include, for example, polyimide nanofoams such as fluorinated tetraethylorthosilicate (FTEOS), hydrogen silsesquioxane (HSQ), bis-benzocyclobutene (BCB), tetramethylorthosilicate (TMOS), octamethyleyclotetrasiloxane (OMCTS), hexamethyldisiloxane (HMDS), trimethylsilyl borate (TMSB), diacetoxyditertiarybutosiloxane (DADBS), trimethylsilil phosphate (TMSP), polytetrafluoroethylene (PTFE), tonen silazen (TOSZ), fluoride silicate glass (FSG), or polypropylene oxide, and carbon doped silicon oxide (CDO), organo silicate glass 9 OSG), SILK, amorphous fluorinated carbon, silica aerogels, silica xerogels, mesoporous silica, and combinations thereof.

In an embodiment, an etch stop layer may be further disposed between the gate spacer 140 and the interlayer insulating layer 190, and between the source/drain patterns 150 and the interlayer insulating layer 190. The etch stop layer may include a material that has etching selectivity with respect to the interlayer insulating layer 190. The etch stop layer 185 may include, for example, at least one of a silicon nitride (SiN), a silicon oxynitride (SiON), a silicon oxycarbonitride (SiOCN), a silicon boron nitride (SiBN), a silicon oxyboron nitride (SiOBN), a silicon oxycarbide (SiOC), and combinations thereof.

The semiconductor device may further include an upper insulation layer 195.

The upper insulation layer 195 may be disposed on the upper side of the capping layer 145 and the upper side of the interlayer insulating layer 190. The upper insulation layer 195 may include the same material as the interlayer insulating layer 190. For example, the upper insulation layer 195 may include at least one of a silicon oxide (SiO₂), a silicon nitride (SiN), a silicon oxynitride (SiON), and low dielectric materials.

The semiconductor device may further include a contact electrode CT.

The contact electrode CT may be disposed on the source/drain patterns 150. The contact electrode CT may pass through the interlayer insulating layer 190 and the upper insulation layer 195. The contact electrode CT may be electrically connected to the source/drain patterns 150.

The bottom side of the contact electrode CT may be disposed, for example, on a similar level to the upper side of the channel pattern disposed on the highest portion from among the channel patterns NS. However, without being limited thereto, the bottom side of the contact electrode CT may be higher or lower than the bottom side of the channel pattern disposed on the highest portion from among the channel patterns NS. In another example, the bottom side of the contact electrode CT may be disposed between a lower surface of the channel pattern disposed on the lowest portion and a lower surface of the channel pattern disposed on the highest portion from among the channel patterns NS.

The contact electrode CT may, for example, include at least one of a metal, a metal alloy, a conductive metal nitride, a conductive metal carbide, a conductive metal oxide, a conductive metal carbonitride, and a two-dimensional (2D) material.

In an embodiment, a silicide layer may be further disposed between the source/drain patterns 150 and the contact electrode CT. The silicide layer may surround a portion of the contact electrode CT indented into the source/drain patterns 150. The silicide layer may include a metal-silicide. For example, the silicide layer may include at least one of a titanium silicide, a tantalum silicide, a tungsten silicide, a nickel silicide, and a cobalt silicide.

The semiconductor device may further include an upper wire structure body 420.

The upper wire structure body 420 may be disposed on the upper insulation layer 195. The upper wire structure body 420 may include upper wires 421 and an upper line insulation layer 422.

The upper wires 421 may be disposed on the upper insulation layer 195. The upper wires 421 may include a metal (e.g., copper). The upper wires 421 may be electrically connected to the contact electrode CT.

The upper line insulation layer 422 may be disposed on the upper insulation layer 195. The upper line insulation layer 422 may cover the upper wire structure body 420. That is, the upper line insulation layer 422 may cover the upper wires 421, and the upper wires 421 may be disposed in the upper line insulation layer 422. The upper line insulation layer 422 may, for example, include at least one of a silicon oxide (SiO₂), a silicon nitride (SiN), a silicon oxynitride (SiON), and low dielectric layers.

The lower wire structure body 410 may be disposed on the second surface 100b of the substrate 100. The lower wire structure body 410 may, for example, be a power delivery network for supplying voltages (e.g., a power supply voltage, etc.) to the source/drain patterns 150.

The lower wire structure body 410 may include lower wires 411 and a lower line insulation layer 412.

The lower wires 411 may be disposed on the second surface 100b of the substrate 100. The lower wires 411 may include a metal (e.g., copper). The lower wires 411 may be electrically connected to the through via 300.

The lower line insulation layer 412 may be disposed on the second surface 100b of the substrate 100. The lower line insulation layer 412 may cover the lower wire structure body 410. That is, the lower line insulation layer 412 may cover the lower wires 411, and the lower wires 411 may be disposed in the lower line insulation layer 412. The lower line insulation layer 412 may, for example, include at least one of a silicon oxide (SiO₂), a silicon nitride (SiN), a silicon oxynitride (SiON), and low dielectric layers.

The through via 300 may be disposed below the landing pad structure 170. The through via 300 may be disposed between the landing pad structure 170 and the lower wire structure body 410. The through via 300 may be connected to one source/drain patterns 150 through the landing pad structure 170. For example, the through via 300 may be electrically connected to the source/drain patterns 150 that are not connected to the contact electrode CT through the landing pad structure 170. However, without being limited thereto, the through via 300 may be electrically connected to the source/drain patterns 150 connected to the contact electrode CT.

The through via 300 may extend to the lower wire structure body 410 from the landing pad structure 170 in the third direction D3. The upper side of the through via 300 may contact the landing pad structure 170. For example, the upper side of the through via 300 may contact the silicide layer 172. In an embodiment, the source/drain patterns 150 may be electrically connected to the lower wire structure body 410 through the through via 300. That is, the voltage (e.g., the power supply voltage, etc.) may be applied to the source/drain patterns 150 from the lower wire structure body 410 through the through via 300.

The through via 300 may include the same material as the contact electrode CT. The through via 300 may, for example, include at least one of a metal, a metal alloy, a conductive metal nitride, a conductive metal carbide, a conductive metal oxide, and a conductive metal carbonitride. However, without being limited thereto, the through via 300 may include a material that is different from the contact electrode CT.

Referring to FIG. 5, the through via 300 of the semiconductor device according to an embodiment may include a first portion 310 contacting the landing pad structure 170 and a second portion 320 disposed between the first portion 310 and the lower wire structure body 410. The first portion 310 may represent a portion of the through via 300 formed in a space from which at least one dummy source/drain pattern 160 is removed.

The first portion 310 may extend from the bottom side of the landing pad structure 170 in the third direction D3. The first portion 310 may overlap the landing pad structure 170 in the third direction D3. The first portion 310 may surround the silicide layer 172. For example, the first portion 310 may surround the first lateral side 172_S1 and the second lateral side 172_S2 of the silicide layer 172. The first portion 310 may overlap the silicide layer 172 in a horizontal direction (e.g., the first direction D1 and/or the second direction D2). The first portion 310 may contact the silicide layer 172. The first portion 310 may be electrically connected to the second portion 320.

In an embodiment, a third width L3 of the first portion 310 in the first direction D1 may increase and may reduce in accordance with a distance from the second surface 100b of the substrate 100. However, without being limited thereto, for example, a first width L1 of the first portion 310 in the first direction D1 may increase in accordance with a distance from the second surface 100b of the substrate 100. This may be caused by a characteristic of a process for forming a first portion 310 in the space from which the dummy source/drain pattern 160 is removed. For another example, the third width L3 of the first portion 310 in the first direction D1 may be constant.

In an embodiment, the third width L3 of the first portion 310 in the first direction D1 may be smaller than a second width L2 of the source/drain patterns 150 in the first direction D1, but is not limited thereto. The third width L3 of the first portion 310 in the first direction D1 may be substantially equal to the fourth width L4 of the dummy source/drain pattern 160 in the first direction D1, but is not limited thereto.

The second portion 320 may be disposed between the first portion 310 and the lower wire structure body 410. The second portion 320 may extend to the second surface 100b of the substrate 100 from the bottom side of the first portion 310 in the third direction D3. That is, the second portion 320 may extend in the third direction D3 and may contact the bottom side of the first portion 310. The second portion 320 may overlap the first portion 310 in the third direction D3. The second portion 320 may pass through the substrate 100 and may contact the lower wire structure body 410. The second portion 320 may be electrically connected to the lower wires 411 of the lower wire structure body 410.

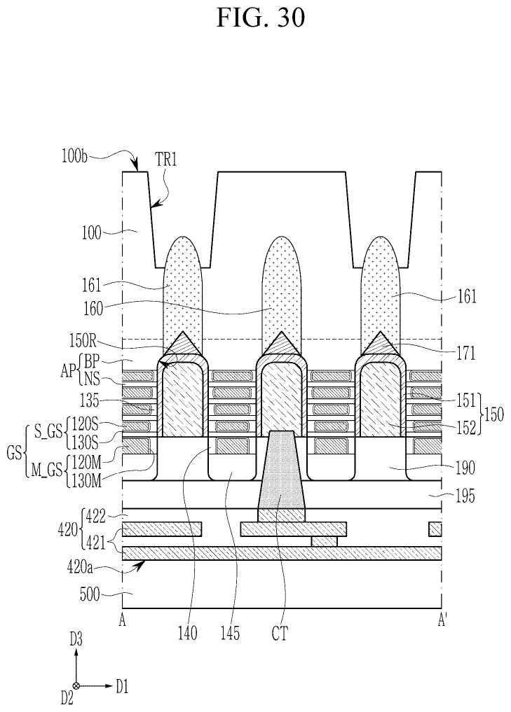

In an embodiment, a bent portion may be disposed on a portion where the second portion 320 contacts the first portion 310. Hence, the width of the second portion 320 in the first direction D1 may be greater than the third width L3 of the first portion 310 in the first direction D1, but is not limited thereto. This may be caused, in the process for forming a second portion 320, by the characteristic of the process for forming a first penetration hole TR1 of FIG. 30 to expose the dummy source/drain pattern 160, etching the exposed dummy source/drain pattern 160 to remove the dummy source/drain pattern 160, forming a first portion 310 in the space from which the dummy source/drain pattern 160 is removed, and forming a second portion 320 in the first penetration hole TR1 of FIG. 30. This will be described later with reference to FIG. 30.

In an embodiment, the second portion 320 may include the same material as the first portion 310. The second portion 320 may be integrally formed with the first portion 310 without a boundary therebetween. However, without being limited thereto, the second portion 320 may include a material that is different from the first portion 310.

The through via 300 may further include an insulating liner disposed on an exterior side of the through via 300 so as to be insulated from the substrate 100.

A semiconductor device according to several embodiments will now be described with reference to FIG. 6 to FIG. 10.

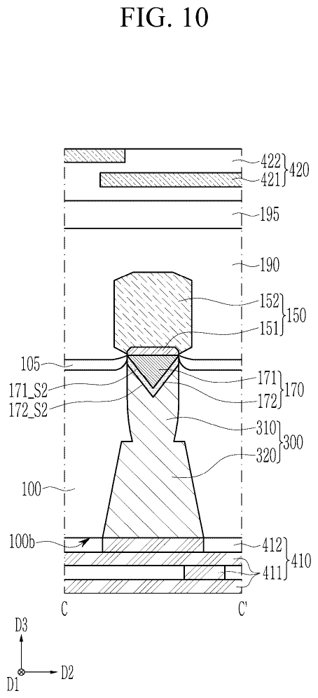

FIG. 6 to FIG. 9 show cross-sectional views that correspond to a region S1 of FIG. 2, showing a semiconductor device according to several embodiments. FIG. 10 shows a cross-sectional view of a semiconductor device according to several embodiments.

The semiconductor device shown in FIG. 6 to FIG. 9 substantially corresponds to the semiconductor device shown in FIG. 1 to FIG. 5, which will be omitted, and differences will be mainly described. The shape of the landing pad 171 is different from the shape discussed above, which will now be described.

Referring to FIG. 6, the landing pad 171 of the semiconductor device according to several embodiments may further include a bottom side 171_B extending in parallel to the second surface 100b of the substrate 100. For example, as shown in FIG. 6, the bottom side 171_B of the landing pad 171 may extend in the first direction D1 on the cross-section formed by the first direction D1 and the third direction D3.

Hence, the silicide layer 172 surrounding the landing pad 171 may further include a bottom side 172_B extending in parallel to the second surface 100b of the substrate 100. For example, as shown in FIG. 6, the bottom side 172_B of the silicide layer 172 may extend in the first direction D1 on the cross-section formed by the first direction D1 and the third direction D3.

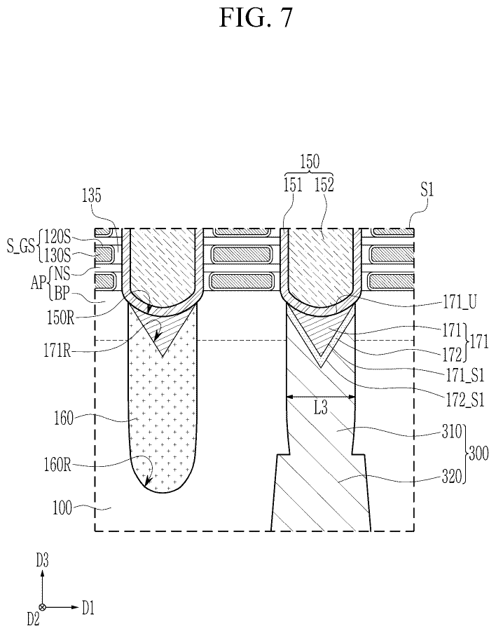

Referring to FIG. 7, the landing pad 171 of the semiconductor device according to several embodiments may cover the bottom side of the source/drain patterns 150. For example, the landing pad 171 may cover the bottom side of the first source/drain pattern 151. Hence, the bottom side of the first source/drain pattern 151 may not contact the bottom pattern BP. The maximum width of the landing pad 171 in the first direction D1 may be substantially equal to the maximum width of the source/drain patterns 150 in the first direction D1, but is not limited thereto. Hence, in several embodiments, the third width L3 of the first portion 310 of the through via 300 in the first direction D1 may be substantially equal to the maximum width of the source/drain patterns 150 in the first direction D1, but is not limited thereto.

In several embodiments, the upper side 171_U of the landing pad 171 may include a curved surface. For example, the upper side 171_U of the landing pad 171 may have a concave shape toward the second surface 100b of the substrate 100. Hence, the bottom side of the source/drain patterns 150 may have a convex shape toward the second surface 100b of the substrate 100.

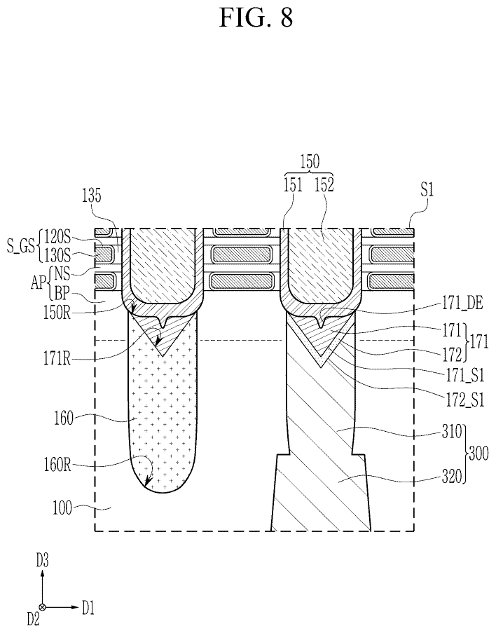

Referring to FIG. 8, the landing pad 171 of the semiconductor device according to several embodiments may further include a dent 171_DE. The dent 171_DE of the landing pad 171 may have a concave shape toward the second surface 100b of the substrate 100. Hence, the upper side of the landing pad 171 may include a concave shape toward the second surface 100b of the substrate 100. This may be caused by the characteristic of the process by which at least a portion of the landing pad 171 is not formed in a process for forming the landing pad 171 in the landing pad recess 171R according to a selective epitaxial growth process by using the dummy source/drain pattern 160 as a seed.

In several embodiments, the source/drain patterns 150 may fill the dent 171_DE of the landing pad 171. For example, the first source/drain pattern 151 may fill the dent 171_DE of the landing pad 171. Hence, the first source/drain pattern 151 may include a protrusion that is convex toward the second surface 100b of the substrate 100, but is not limited thereto. This may be caused by the characteristic of the process for forming source/drain patterns 150 according to the selective epitaxial growth process by using the landing pad 171 as a seed.

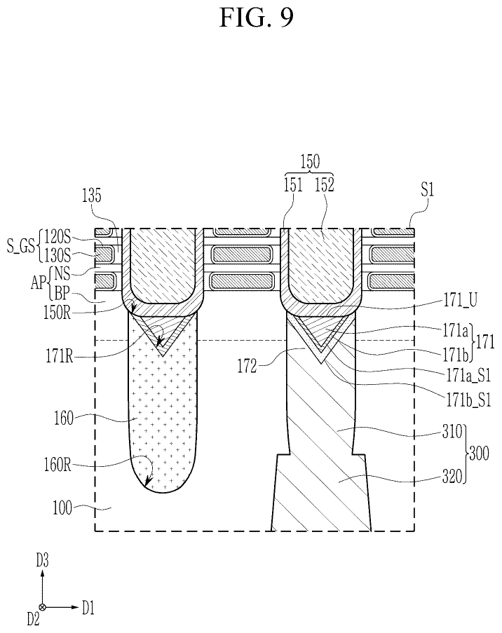

Referring to FIG. 9, the landing pad 171 of the semiconductor device according to several embodiments may include a first landing pad 171a disposed on a bottom side of the source/drain patterns 150 and a second landing pad 171b surrounding the first landing pad 171a.

The first landing pad 171a may be disposed on the bottom side of the first source/drain pattern 151. The first landing pad 171a may protrude toward the second surface 100b of the substrate 100 from the bottom side of the first source/drain pattern 151. For example, as shown in FIG. 9, the width of the first landing pad 171a in the first direction D1 may reduce in accordance with a distance from the bottom side of the first source/drain pattern 151 on the cross-section formed by the first direction D1 and the third direction D3. That is, the width of the first landing pad 171a in the first direction D1 may increase in accordance with a distance from the second surface 100b of the substrate 100.

In several embodiments, the lateral side of the first landing pad 171a may be inclined from the second surface 100b of the substrate 100. For example, as shown in FIG. 9, the first landing pad 171a may include a first lateral side 171_S1 inclined from the second surface 100b of the substrate 100 by a predetermined angle on the cross-section formed by the first direction D1 and the third direction D3. The first lateral side 171a_S1 of the first landing pad 171a may be flat, but is not limited thereto. That is, the first lateral side 171a_S1 of the first landing pad 171a may extend straight on the cross-section formed by the first direction D1 and the third direction D3. The first lateral side 171a_S1 of the first landing pad 171a may represent the lateral side of the first landing pad 171a on the cross-section formed by the first direction D1 and the third direction D3.

In several embodiments, a first element may be doped into the first landing pad 171a. That is, the first landing pad 171a may include the same material as the first element doped into the source/drain patterns 150. For example, when the semiconductor device is a P-type semiconductor device, the first element may include boron (B), carbon (C), or combinations thereof, but is not limited thereto. The concentration of the first element in the landing pad 171 may be about 8×10²⁰ cm⁻³ to about 5×10²¹ cm⁻³.

The second landing pad 171b may surround the first landing pad 171a. For example, the second landing pad 171b may be disposed on the first lateral side 171a_S1 of the first landing pad 171a. The second landing pad 171b may be disposed between the first landing pad 171a and the silicide layer 172. The second landing pad 171b may be disposed along an interface of the first landing pad 171a facing the through via 300. For example, the second landing pad 171b may be disposed with a uniform thickness on the first lateral side 171a_S1 of the first landing pad 171a.

In several embodiments, the lateral side of the second landing pad 171b may include a surface inclined from the second surface 100b of the substrate 100. For example, as shown in FIG. 9, the second landing pad 171b may include a first lateral side 171b_S1 inclined from the second surface 100b of the substrate 100 by a predetermined angle on the cross-section formed by the first direction D1 and the third direction D3. The first lateral side 171b_S1 of the second landing pad 171b may be flat, but is not limited thereto. That is, first lateral side 171b_S1 of the second landing pad 171b may extend straight on the cross-section formed by the first direction D1 and the third direction D3.

In several embodiments, the second element that is different from the first element may be doped into the second landing pad 171b. That is, the second landing pad 171b may include a material that is different from the first landing pad 171a. For example, the second element may include boron (B), carbon (C), or combinations thereof, but is not limited thereto.

Referring to FIG. 10, the landing pad 171 of the semiconductor device according to several embodiments may not include a bottom side extending in parallel to the second surface 100b of the substrate 100. For example, as shown in FIG. 10, the landing pad 171 may have a triangle shape on the cross-section formed by the second direction D2 and the third direction D3. In this case, an interface where the landing pad 171 contacts the silicide layer 172 may be formed with the second lateral side 172_S2 inclined from the second surface 100b of the substrate 100 by a predetermined angle. The silicide layer 172 of the semiconductor device according to several embodiments may not include a bottom side extending in parallel to the second surface 100b of the substrate 100.

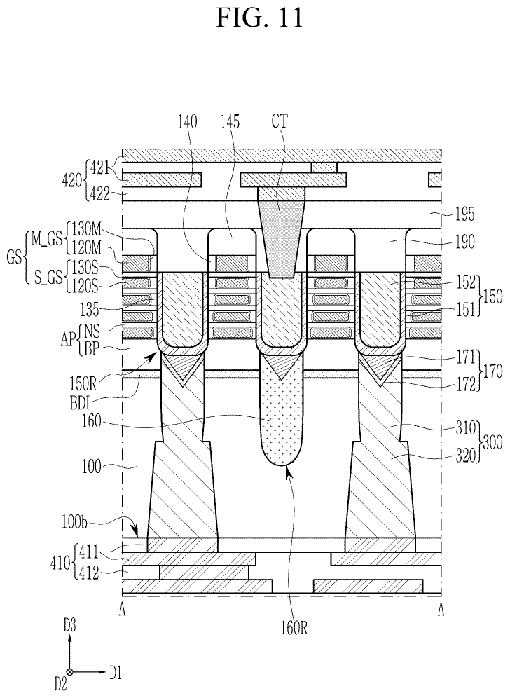

A semiconductor device according to several embodiments will now be described with reference to FIG. 11.

FIG. 11 shows a cross-sectional view of a semiconductor device according to several embodiments.

The semiconductor device shown in FIG. 11 substantially corresponds to the semiconductor device shown in FIG. 1 to FIG. 5, which will not be described, and differences will be mainly described. The semiconductor device shown in FIG. 11 further includes a bottom dielectric isolation structure (BDI), which is different from the previous embodiment, and will now be described.

Referring to FIG. 11, the semiconductor device according to several embodiments may further include a bottom dielectric isolation structure (BDI) disposed between the bottom pattern BP and the substrate 100. The bottom dielectric isolation structure (BDI) may include various insulating materials. For example, the bottom dielectric isolation structure (BDI) may include a silicon oxide, a silicon nitride, a silicon oxynitride, or combinations thereof. The bottom dielectric isolation structure (BDI) may space the bottom pattern BP and the substrate 100. In several embodiments, the through via 300 and the dummy source/drain pattern 160 may penetrate the bottom dielectric isolation structure (BDI).

FIG. 11 shows that the bottom dielectric isolation structure (BDI) is disposed between the bottom pattern BP and the substrate 100, but is not limited thereto. For example, the bottom dielectric isolation structure (BDI) may be disposed in the bottom pattern BP.

FIG. 11 also shows that the bottom dielectric isolation structure (BDI) has a single layer, but is not limited thereto. For example, the bottom dielectric isolation structure (BDI) may have a multilayer including insulating layers.

A method for manufacturing a semiconductor device according to an embodiment will now be described with reference to FIG. 12 to FIG. 38.

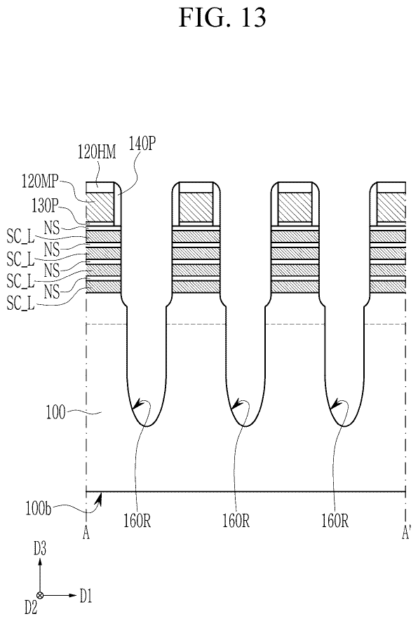

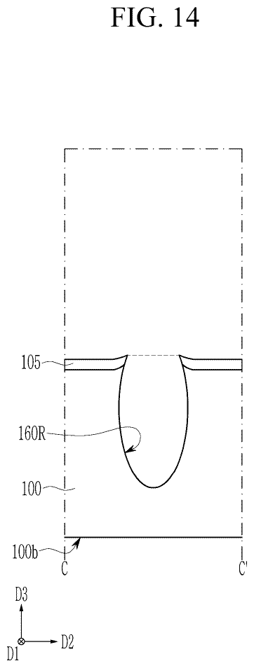

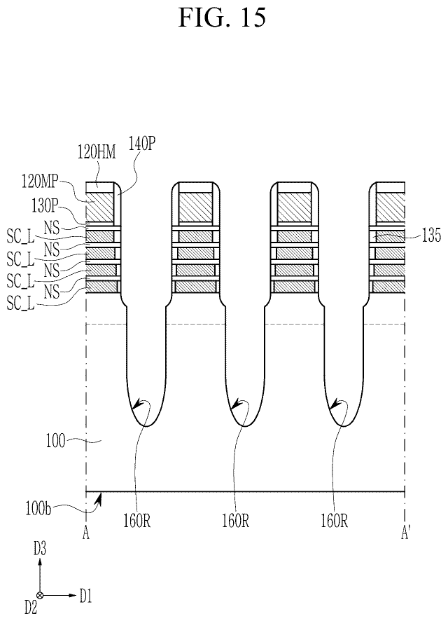

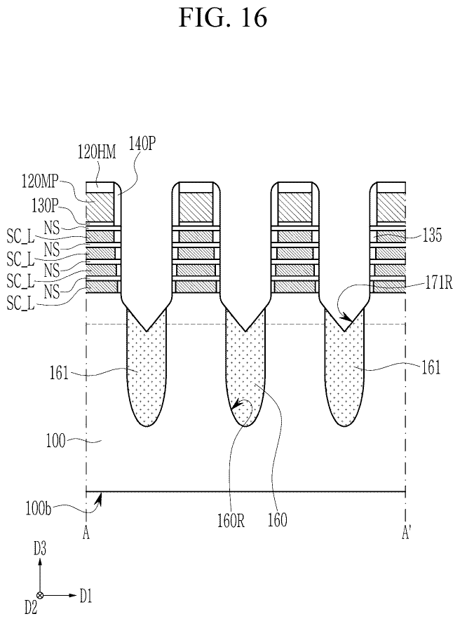

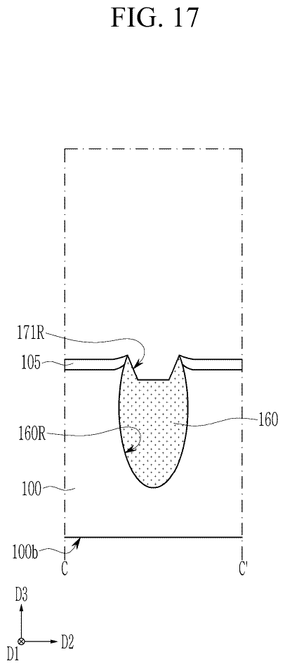

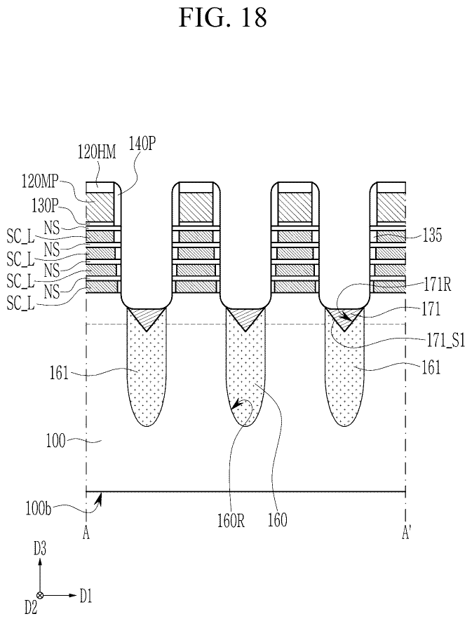

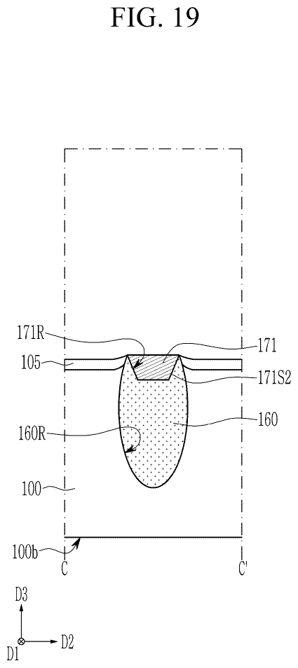

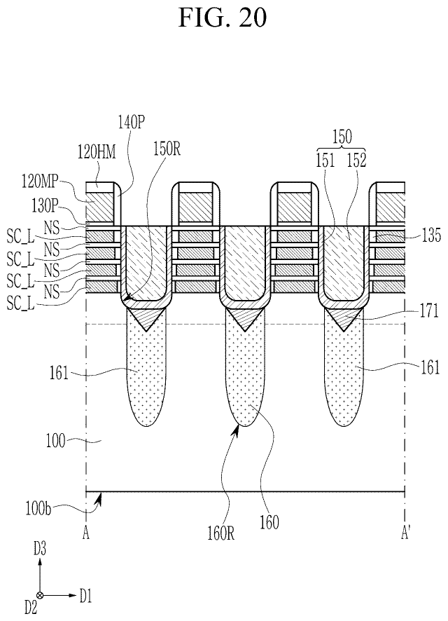

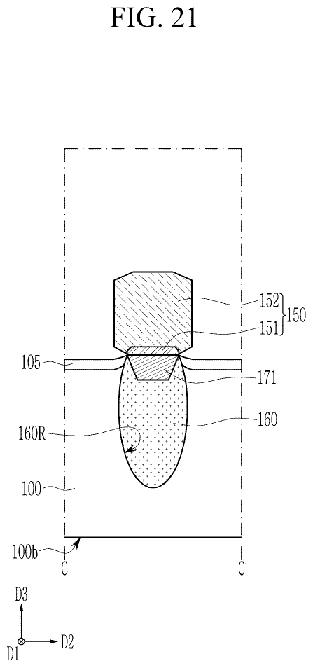

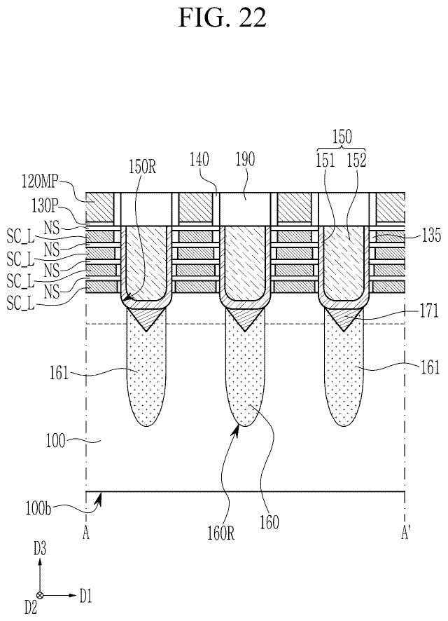

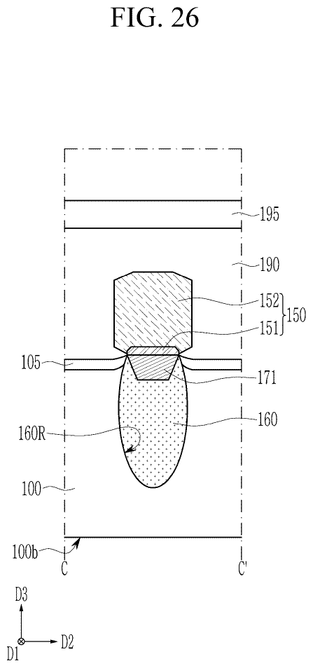

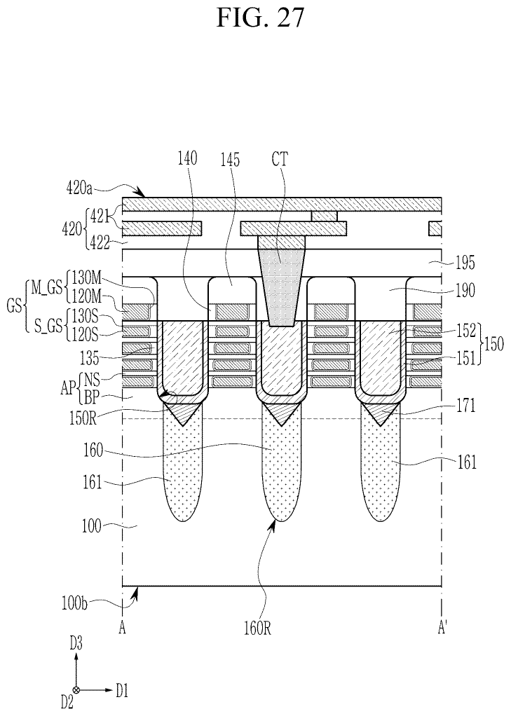

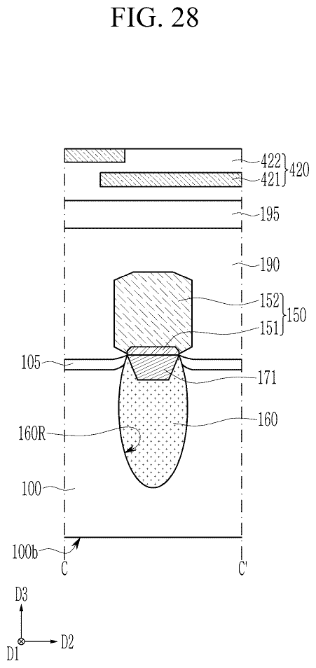

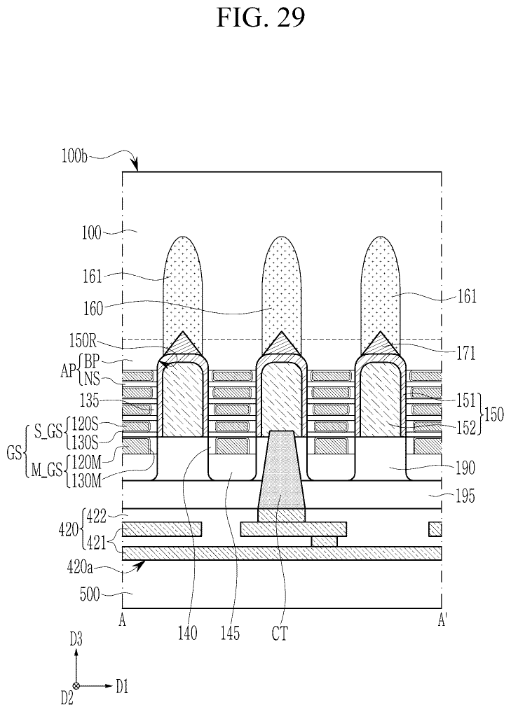

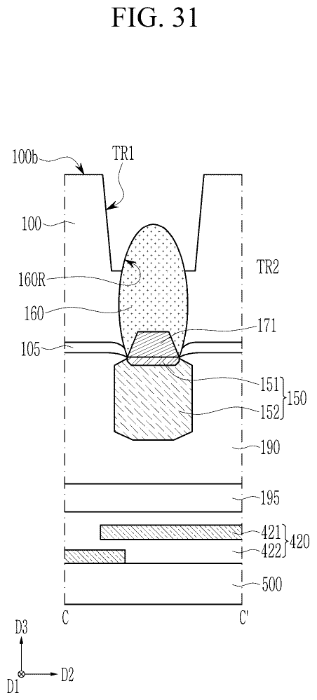

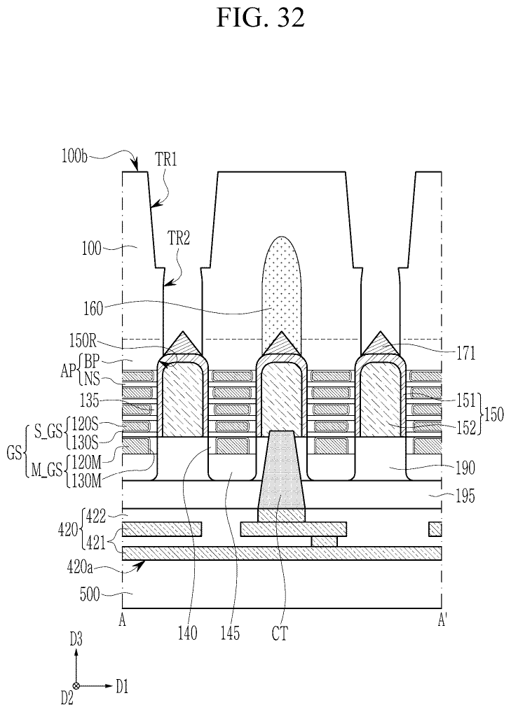

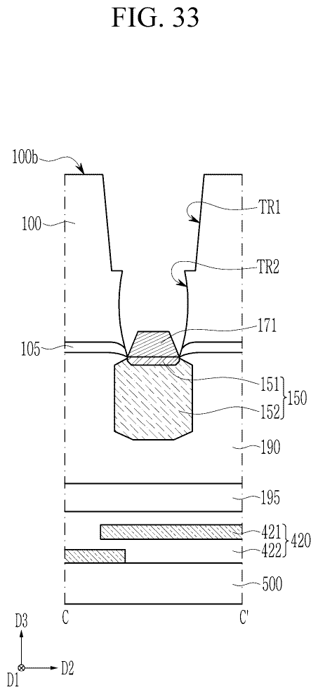

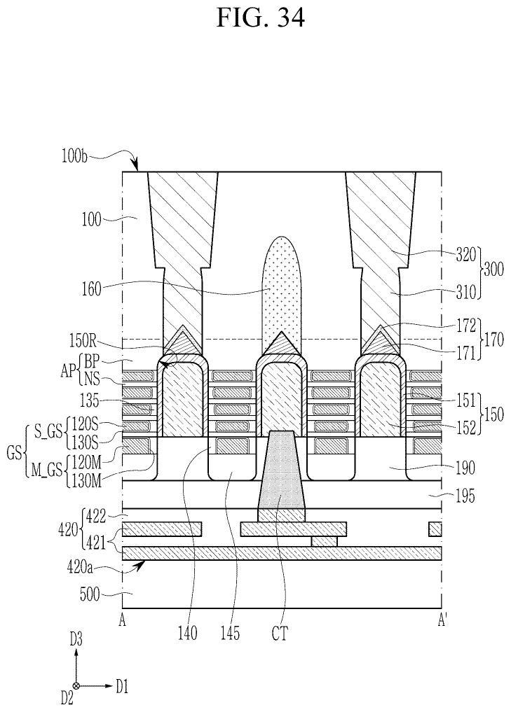

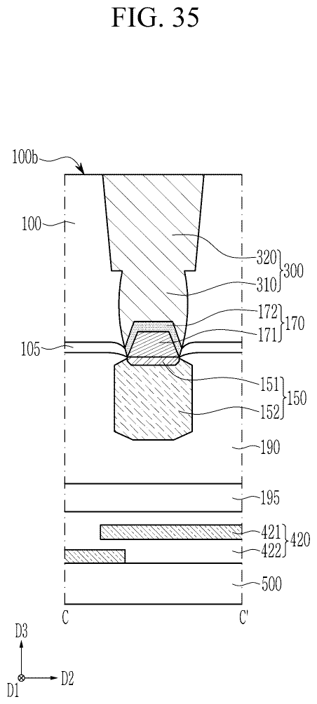

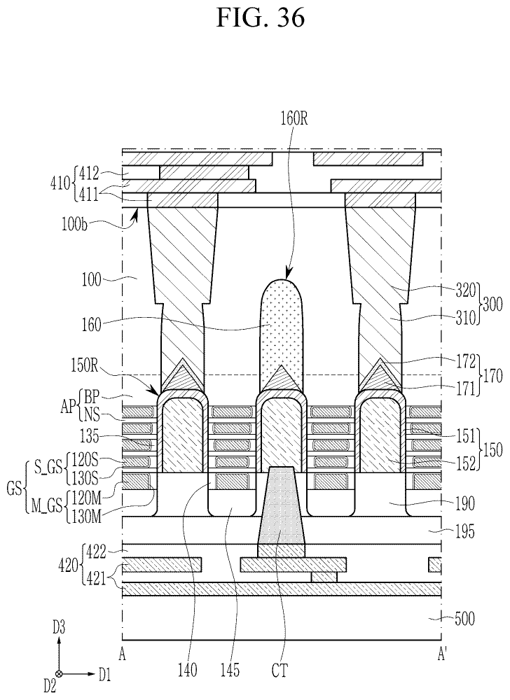

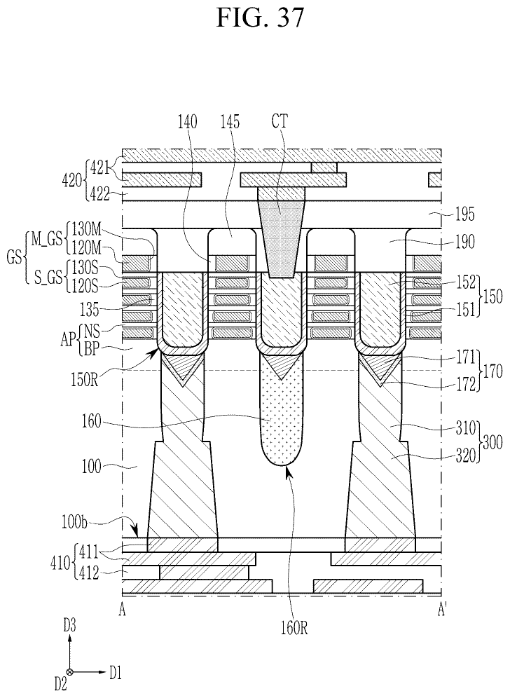

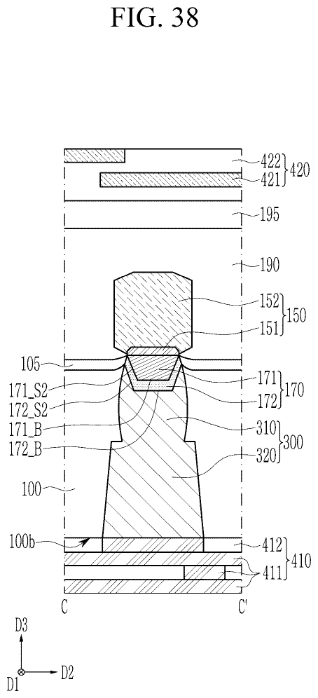

FIG. 12 to FIG. 38 show cross-sectional views of intermediate stages of a method for manufacturing a semiconductor device according to an embodiment. FIG. 12, FIG. 13, FIG. 15, FIG. 16, FIG. 18, FIG. 20, FIG. 22 to FIG. 25, FIG. 27, FIG. 29, FIG. 30, FIG. 32, FIG. 34, FIG. 36, and FIG. 37 show cross-sectional views of the method for manufacturing a semiconductor device according to an embodiment with respect to a line A-A′ of FIG. 1. FIG. 14, FIG. 17, FIG. 19, FIG. 21, FIG. 26, FIG. 28, FIG. 31, FIG. 33, FIG. 35, and FIG. 38 show cross-sectional views of the method for manufacturing a semiconductor device according to an embodiment with respect to a line B-B′ of FIG. 1.

As shown in FIG. 12, an upper pattern structure body U_AP may be formed on the substrate 100, and a preliminary gate insulating layer 130P, a preliminary main gate electrode 120MP, and a preliminary capping layer 120_HM are formed.

First, the upper pattern structure body U_AP is formed on the substrate 100. The substrate 100 may be a silicon-on-insulator (SOI) or bulk silicon. Differing from this, the substrate 100 may be a silicon substrate, or may include other materials, for example, silicon germanium (SiGe), silicon germanium on insulator (SGOI), an indium antimonide, a lead telluride compound, indium arsenic, indium phosphide, gallium arsenic, or a gallium antimonide, but is not limited thereto.

The substrate 100 may include a first surface and a second surface 100b. The first surface and the second surface 100b of the substrate 100 may be made of planes in parallel to the first direction D1 and the second direction D2 crossing the first direction D1. The first surface of the substrate 100 may oppose the second surface 100b of the substrate 100 in the third direction D3. The first surface of the substrate 100 may be referred to as an upper side or a front side of the substrate 100. The second surface 100b of the substrate 100 may be referred to as a bottom side or a back side of the substrate 100. In several embodiments, a logic circuit of the cell region may be realized on the first surface of the substrate 100.

The upper pattern structure body U_AP may be disposed on the first surface of the substrate 100. The upper pattern structure body U_AP may include a sacrificial pattern SC_L and an active pattern ACT_L alternately stacked on the substrate 100. For example, the sacrificial pattern SC_L may include silicon germanium (SiGe). The active pattern ACT_L may include silicon (Si).

A preliminary gate insulating layer 130P, a preliminary main gate electrode 120MP, and a preliminary capping layer 120_HM are formed on the upper pattern structure body U_AP. The preliminary gate insulating layer 130P may, for example, include a silicon oxide (SiO₂), and is not limited thereto. The preliminary main gate electrode 120MP may, for example, include polysilicon, and is not limited thereto. The preliminary capping layer 120_HM may, for example, include a silicon nitride, and is not limited thereto.

A preliminary gate spacer 140P may be formed on respective sides of the preliminary main gate electrode 120MP.

As shown in FIG. 13 and FIG. 14, by using the preliminary main gate electrode 120MP and the preliminary gate spacer 140P as masks, at least a portion of the upper pattern structure body U_AP and the substrate 100 are etched to form a dummy source/drain recess 160R. The dummy source/drain recess 160R may penetrate the upper pattern structure body U_AP. The dummy source/drain recess 160R may penetrate at least a portion of the substrate 100. That is, a portion of the dummy source/drain recess 160R may be formed in the substrate 100.

As the dummy source/drain recess 160R is formed, the active pattern ACT_L may be separated and channel patterns NS may be formed. The channel patterns NS may be disposed on respective sides of the dummy source/drain recess 160R. The channel patterns NS and the sacrificial pattern SC_L may be alternately stacked.

As shown in FIG. 15, a portion of the lateral side of the exposed sacrificial pattern SC_L may be removed, and an inner gate spacer 135 may be formed in the removed space. The inner gate spacer 135 may be formed on the lateral side of the sacrificial pattern SC_L. However, without being limited thereto, the process for forming the inner gate spacer 135 may be omitted.

As shown in FIG. 16 and FIG. 17, a dummy source/drain pattern 160 may be formed in the dummy source/drain recess 160R.

The dummy source/drain pattern 160 may be formed on the substrate 100. The dummy source/drain pattern 160 may contact the substrate 100. The upper side of the dummy source/drain pattern 160 may be formed lower than the bottom side of the sacrificial pattern SC_L. The dummy source/drain pattern 160 may be formed by the epitaxial growth process using the substrate 100 as a seed. According to growing conditions of the dummy source/drain pattern 160, the upper side of the dummy source/drain pattern 160 may be inclined from the second surface 100b of the substrate 100 by a predetermined angle. Hence, a landing pad recess 171R may be formed on an upper portion of the dummy source/drain pattern 160.

The dummy source/drain pattern 160 may include a first material and a second material. The second material may be different from the first material. The second material may, for example, include carbon (C), silicon (Si), germanium (Ge), and tin (Sn).

In an embodiment, the dummy source/drain pattern 160 may include a dummy pattern 161 to be removed in a subsequent process for forming a through via 300. That is, a portion of the dummy source/drain pattern 160 may be a dummy pattern for forming a through via 300 of FIG. 2. In a subsequent process, the dummy pattern 161 may be removed, and the through via 300 of FIG. 2 may be formed in the removed space. For better understanding and ease of description, the dummy source/drain pattern 160 removed to form the through via 300 of FIG. 2 will be referred to as the dummy pattern 161.

Referring to FIG. 18 and FIG. 19, the landing pad 171 may be formed on the dummy source/drain pattern 160. The landing pad 171 may fill the landing pad recess 171R. The landing pad 171 may contact the dummy source/drain pattern 160. The upper side of the landing pad 171 may be formed lower than the bottom side of the sacrificial pattern SC_L. The landing pad 171 may be formed by the epitaxial growth process using the dummy source/drain pattern 160 as the seed.

In an embodiment, the lateral side of the landing pad 171 may include a side inclined from the second surface 100b of the substrate 100. For example, as shown in FIG. 18, the landing pad 171 may include a first lateral side 171_S1 inclined from the second surface 100b of the substrate 100 by a predetermined angle on the cross-section formed by the first direction D1 and the third direction D3. The first lateral side 171_S1 of the landing pad 171 may be flat, but is not limited thereto. That is, the first lateral side 171_S1 of the landing pad 171 may extend straight on the cross-section formed by the first direction D1 and the third direction D3. The first lateral side 171_S1 of the landing pad 171 may represent a lateral side of the landing pad 171 on the cross-section formed by the first direction D1 and the third direction D3.

As shown in FIG. 19, the landing pad 171 may include a second lateral side 171_S2 inclined from the second surface 100b of the substrate 100 by a predetermined angle on the cross-section formed by the second direction D2 and the third direction D3. The second lateral side 171_S2 of the landing pad 171 may be flat, but is not limited thereto. That is, the second lateral side 171_S2 of the landing pad 171 may extend straight on the cross-section formed by the second direction D2 and the third direction D3. The angle between the second lateral side 171_S2 of the landing pad 171 and the second surface 100b of the substrate 100 may be substantially equal to the angle between the first lateral side 171_S1 of the landing pad 171 and the second surface 100b of the substrate 100, but is not limited thereto. For example, the angle between the second lateral side 171_S2 of the landing pad 171 and the second surface 100b of the substrate 100 may be different from the angle between the first lateral side 171_S1 of the landing pad 171 and the second surface 100b of the substrate 100. The second lateral side 171_S2 of the landing pad 171 may represent the lateral side of the landing pad 171 on the cross-section formed by the second direction D2 and the third direction D3.

In an embodiment, the landing pad 171 may further include a bottom side 171_B extending in parallel to the second surface 100b of the substrate 100. For example, as shown in FIG. 19, the bottom side of the landing pad 171 may extend in the second direction D2 on the cross-section formed by the second direction D2 and the third direction D3. However, without being limited thereto, for example, the bottom side of the landing pad 171 may extend in the first direction D1.

The upper side of the landing pad 171 may be flat or may include a concave portion that curves toward the second surface 100b of the substrate 100. As the landing pad 171 is formed, a source/drain recess 150R defined by the upper side of the landing pad 171, the lateral side of the channel patterns NS, and the lateral side of the inner gate spacer 140 may be formed.

The landing pad 171 may include a semiconductor material. The landing pad 171 may include the same material as the source/drain patterns 150. For example, the landing pad 171 may include a first material and a second material that is different from the first material. For example, the first material may include silicon (Si), and the second material may include germanium (Ge).

In an embodiment, impurities may be doped into the landing pad 171. For example, the landing pad 171 may include the same material as the first element doped into the source/drain patterns 150. For example, when the semiconductor device is a P-type semiconductor device, the first element may include boron (B). However, without being limited thereto, for another example, when the semiconductor device is an N-type semiconductor device, the first element may include boron (B), carbon (C), and combinations thereof.

Referring to FIG. 20 and FIG. 21, a source/drain patterns 150 may be formed on the landing pad 171. The source/drain patterns 150 may be formed by using the epitaxial growth method using the landing pad 171 and the channel patterns NS as seeds. In detail, the first source/drain pattern 151 may be formed along a sidewall and a bottom side of the source/drain recess 150R. A second source/drain pattern 152 may be formed on the first source/drain pattern 151.

The first source/drain pattern 151 may include a first material. The first material may include a semiconductor material. The first material may, for example, include a semiconductor material such as silicon (Si) or germanium (Ge).

The second source/drain pattern 152 may include the same material as the dummy source/drain pattern 160. The second source/drain pattern 152 may include a first material and a second material. The second material may, for example, include carbon (C), silicon (Si), germanium (Ge), and tin (Sn). For example, the first source/drain pattern 151 may include silicon (Si), and the second source/drain pattern 152 may include silicon germanium (SiGe). However, without being limited thereto, for another example, the second source/drain pattern 152 may include the same material as the first source/drain pattern 151, and the second source/drain pattern 152 and the first source/drain pattern 151 may have different concentrations of configured materials. For example, when the second source/drain pattern 152 and the first source/drain pattern 151 include silicon germanium (SiGe), the concentration of germanium (Ge) of the second source/drain pattern 152 may be greater than the concentration of germanium (Ge) of the first source/drain pattern 151.

In an embodiment, the first element may be doped into the first source/drain pattern 151 and the second source/drain pattern 152. When the semiconductor device is a P-type semiconductor device, the first element may be P-type impurities. For example, the first element may include B, V, In, Ga, Al, or combinations thereof. The concentration of the first element in the first source/drain pattern 151 may be different from the concentration of the first element in the second source/drain pattern 152. For example, the concentration of the first element doped to the second source/drain pattern 152 may be greater than the concentration of the first element doped to the first source/drain pattern 151.

The concentration of the first element in the source/drain patterns 150 may be equal to or smaller than the concentration of the first element in the landing pad 171. The concentration of the first element in the landing pad 171 may be greater than the concentration of the first element in the first source/drain pattern 151. For example, the concentration of the first element in the landing pad 171 may be about 8×10²⁰ cm⁻³ to about 5×10²¹ cm⁻³. The concentration of the first element in the landing pad 171 may be equal to or greater than the concentration of the first element in the second source/drain pattern 152.

As shown in FIG. 22, an interlayer insulating layer 190 may be formed on the source/drain patterns 150. An upper side of the preliminary main gate electrode 120MP is exposed by removing a portion of the interlayer insulating layer 190 and the preliminary capping layer 120_HM. A portion of the preliminary gate spacer 140P is removed together and a gate spacer 140 may be formed.

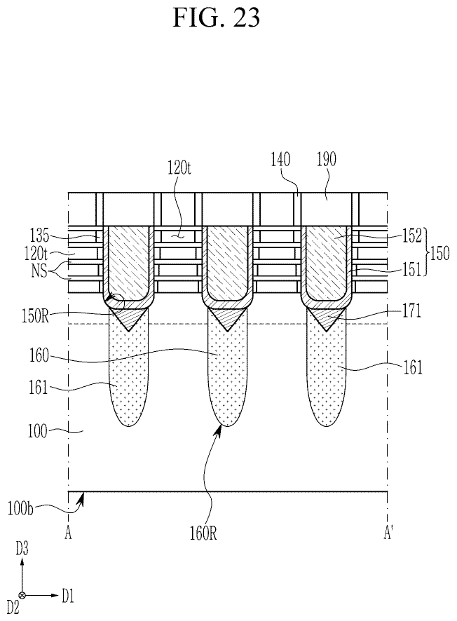

As shown in FIG. 23, the upper pattern structure body U_AP between the gate spacer 140 is exposed by removing the preliminary gate insulating layer 130P and the preliminary main gate electrode 120MP. A gate trench 120t is formed between the channel patterns NS by removing the sacrificial pattern SC_L.

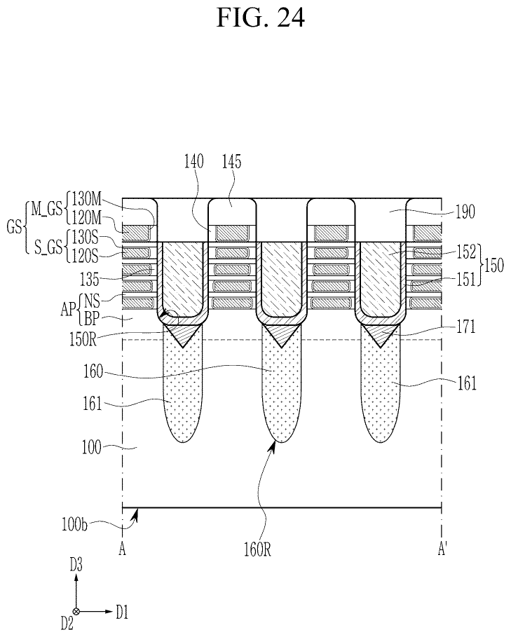

As shown in FIG. 24, a sub-gate insulating layer 130S and a sub-gate electrode 120S may be sequentially formed in the gate trench 120t. A main gate insulating layer 130M, a main gate electrode 120M, and a capping layer 145 may be sequentially formed.

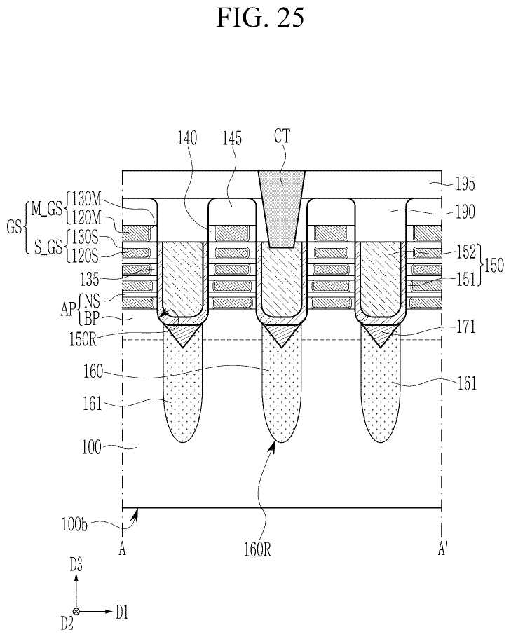

As shown in FIG. 25 and FIG. 26, an upper insulation layer 195 may be formed on the interlayer insulating layer 190, and a contact electrode CT penetrating the upper insulation layer 195 and the interlayer insulating layer 190 may be formed.

An upper insulation layer 195 may be formed to cover the upper side of the interlayer insulating layer 190 and the upper side of the capping layer 145. The upper insulation layer 195 may include the same material as the interlayer insulating layer 190. For example, the upper insulation layer 195 may include at least one of a silicon oxide (SiO₂), a silicon nitride (SiN), a silicon oxynitride (SiON), and a low dielectric material.

A contact hole for penetrating the upper insulation layer 195 and the interlayer insulating layer 190 and exposing the source/drain patterns 150 may be formed. For example, a contact hole penetrating the upper insulation layer 195 and the interlayer insulating layer 190 and exposing the source/drain patterns 150 may be formed. The contact hole may not be formed in the source/drain patterns 150 disposed on the dummy pattern 161, but is not limited thereto.

A contact electrode CT filling contact hole and electrically connected to the source/drain patterns 150 is formed. Hence, the contact electrode CT may penetrate the upper insulation layer 195 and the interlayer insulating layer 190 and may be electrically connected to the source/drain patterns 150.

As shown in FIG. 27 and FIG. 28, an upper wire structure body 420 may be formed on the upper insulation layer 195. The upper wire structure body 420 may include upper wires 421 and an upper line insulation layer 422. The upper wires 421 may be formed on the upper insulation layer 195. The upper wires 421 may include a metal (e.g., copper). The upper wires 421 may be electrically connected to the contact electrode CT.

As shown in FIG. 29, the substrate 100 is disposed on a carrier substrate 500 and the semiconductor device is rotated. An upper side 420a of the upper wire structure body 420 is disposed to face the carrier substrate 500, and the substrate 100 is attached to the carrier substrate 500. An adhesive member may be further disposed between the upper side 420a of the upper wire structure body 420 and the carrier substrate 500.

The carrier substrate 500 may have substantially the same area as the substrate 100 or may have a greater area than the substrate 100. The carrier substrate 500 may, for example, be a semiconductor wafer, a ceramic substrate, or a glass substrate.

As shown in FIG. 30 and FIG. 31, a first penetration hole TR1 for exposing the dummy pattern 161 may be formed by patterning the substrate 100. The process for forming the first penetration hole TR1 may be performed by using a dry etching process, but is not limited thereto. As the first penetration hole TR1 is formed, at least a portion of the dummy pattern 161 may be exposed. A lateral side of the first penetration hole TR1 may be formed of, for example, the substrate 100. A bottom side of the first penetration hole TR1 may be formed of, for example, the substrate 100 and the dummy pattern 161.

Before forming the first penetration hole TR1, an etching process may be performed to remove the substrate 100, and an insulating substrate including an insulating material may be formed in the removed space. Regarding the insulating substrate, an insulating material layer may be formed to cover the dummy source/drain pattern 160 and the dummy pattern 161, and an upper side of the insulating substrate 100 may be planarized by performing a chemical mechanical polishing (CMP) process, to which the insulating substrate is not limited.

As shown in FIG. 32 and FIG. 33, a second penetration hole TR2 may be formed by performing an etching process and removing the exposed dummy pattern 161.

The etching process may be performed as, for example, a dry etching method, but is not limited thereto. The dummy pattern 161 may include a material that has etching selectivity with respect to the landing pad 171. For example, when the dummy pattern 161 and the landing pad 171 include silicon germanium (SiGe), the content (at %) of germanium (Ge) of the dummy pattern 161 may be smaller than the content (at %) of germanium (Ge) of the landing pad 171. Further, the dummy pattern 161 may not include the first element, and the landing pad 171 may include the first element. The first element may include, for example, boron (B), carbon (C), and combinations thereof. Hence, the landing pad 171 may not be etched in the process for removing the dummy pattern 161. The dummy pattern 161 may include a material that has etching selectivity with respect to the substrate 100.

As the dummy pattern 161 is removed, the landing pad 171 may be exposed.

As shown in FIG. 34 and FIG. 35, a through via 300 filling the first penetration hole TR1 and the second penetration hole TR2, and electrically connected to the landing pad 171 is formed.

A first portion 310 may be formed in the region from which the dummy pattern 161 is removed, and a second portion 320 filling the first penetration hole TR1 electrically connected to the first portion 310 may be formed. The through via 300 may cover the source/drain patterns 150 and may fill the first penetration hole TR1 and the second penetration hole TR2.

The through via 300 may be formed by forming a preliminary conductive layer filling an inner sidewall of the first penetration hole TR1, an inner lateral side of the second penetration hole TR2, a bottom side of the second penetration hole TR2, the first penetration hole TR1, and the second penetration hole TR2 and covering a portion of the second surface 100b of the substrate 100, and removing a portion of the preliminary conductive layer covering a portion of the second surface 100b of the substrate 100. The preliminary conductive layer may, for example, include at least one of a metal, a metal alloy, a conductive metal nitride, a conductive metal carbide, a conductive metal oxide, and a conductive metal carbonitride.

In an embodiment, a silicide layer 172 may be formed together in the process for forming a through via in the landing pad 171. The silicide layer 172 may be disposed along an interface of the landing pad 171 exposed by the second penetration hole TR2. The silicide layer 172 may be formed between the through via 300 and the landing pad 171. The silicide layer 172 may contact the through via 300 and the landing pad 171.

As shown in FIG. 36, a lower wire structure body 410 electrically connected to the through via 300 is formed on the second surface 100b of the substrate 100.

The lower wire structure body 410 may include lower wires 411 and a lower line insulation layer 412. The lower wires 411 may be disposed on the second surface 100b of the substrate 100. The lower wires 411 may include a metal (e.g., copper). The lower wires 411 may be electrically connected to the through via 300.

The lower line insulation layer 412 may be disposed on the second surface 100b of the substrate 100. The lower line insulation layer 412 may cover the lower wire structure body 410. That is, the lower line insulation layer 412 may cover the lower wires 411, and the lower wires 411 may be disposed in the lower line insulation layer 412. The lower line insulation layer 412 may, for example, include at least one of a silicon oxide (SiO₂), a silicon nitride (SiN), a silicon oxynitride (SiON), and low dielectric layers.

As shown in FIG. 37 and FIG. 38, the carrier substrate 500 of the semiconductor device according to an embodiment may be removed, and the semiconductor device may be rotated to thus form the semiconductor device of FIG. 1 to FIG. 5.

While aspects of embodiments have been particularly shown and described, it will be understood that various changes in form and details may be made therein without departing from the spirit and scope of the following claims.

What is claimed is:

1. A semiconductor device comprising:
a substrate;
a channel pattern;
a source/drain pattern on the substrate;
a lower wire structure body on a bottom side of the substrate;
a through via penetrating the substrate and connected between the source/drain pattern and the lower wire structure body; and
a landing pad between the through via and the source/drain pattern,
wherein a first element is doped to the source/drain pattern and the landing pad, such that concentration of the first element in the landing pad is equal to or greater than concentration of the first element in the source/drain pattern.

2. The semiconductor device of claim 1, wherein the source/drain pattern comprises:
a first source/drain pattern on a lateral side of the channel pattern and the landing pad; and
a second source/drain pattern on the first source/drain pattern, and
wherein the concentration of the first element in the landing pad is greater than concentration of the first element in the first source/drain pattern.

3. The semiconductor device of claim 2, wherein the landing pad contacts the first source/drain pattern and is spaced apart from the second source/drain pattern.

4. The semiconductor device of claim 1, wherein the source/drain pattern comprises silicon germanium, and the first element comprises boron, carbon, or a combination thereof.

5. The semiconductor device of claim 4, wherein the concentration of the first element in the landing pad is 8×10²⁰ cm⁻³ to 5×10²¹ cm⁻³.

6. The semiconductor device of claim 1, wherein a width of the landing pad in one direction is smaller than a width of the source/drain pattern in the one direction.

7. The semiconductor device of claim 6, wherein the landing pad comprises a lateral side inclined from a bottom side of the substrate.

8. The semiconductor device of claim 7, wherein the landing pad further comprises a bottom side extending in a parallel direction to the bottom side of the substrate.

9. The semiconductor device of claim 6, wherein an upper side of the landing pad extends in a parallel direction to a bottom side of the substrate or has a concave shape toward a bottom side of the substrate.

10. The semiconductor device of claim 6, further comprising a gate structure body on the channel pattern,
wherein the landing pad does not overlap the gate structure body along a vertical direction perpendicular to the bottom side of the substrate.

11. The semiconductor device of claim 1, further comprising:
another source/drain pattern connected to the source/drain pattern through the channel pattern; and
a dummy source/drain pattern between the substrate and at least one source/drain pattern among the source/drain pattern and the other source/drain pattern,
wherein the landing pad extends between the dummy source/drain pattern and the at least one source/drain pattern.

12. The semiconductor device of claim 11, wherein the landing pad comprises a material having etching selectivity with respect to the dummy source/drain pattern.

13. The semiconductor device of claim 11, wherein the dummy source/drain pattern and the landing pad comprise silicon germanium, and the first element comprises boron, and
wherein content (at %) of germanium in the dummy source/drain pattern is smaller than content (at %) of germanium of the landing pad.

14. The semiconductor device of claim 1, further comprising another source/drain pattern connected to the source/drain pattern through the channel pattern,
wherein the landing pad comprises:
a first landing pad on a bottom side of a source/drain pattern and comprising the first element; and
a second landing pad surrounding the first landing pad, wherein a second material that is different from the first element is doped to the second landing pad.

15. A semiconductor device comprising:
a substrate;
a channel pattern on the substrate extending in one direction;
a source/drain pattern contacting a side of the channel pattern, and comprising a first source/drain pattern and a second source/drain pattern on the first source/drain pattern;
a lower wire structure body on a bottom side of the substrate;
a through via penetrating the substrate and connected between the first source/drain pattern and the lower wire structure body; and
a landing pad between the through via and the first source/drain pattern,
wherein a first element is doped to the first source/drain pattern and the landing pad, such that concentration of the first element in the landing pad is greater than concentration of the first element in the first source/drain pattern, and
wherein a maximum width of the landing pad in the one direction is smaller than a maximum width of the source/drain pattern in the one direction.

16. The semiconductor device of claim 15, wherein the maximum width of the landing pad in another direction crossing the one direction is smaller than the maximum width of the source/drain pattern in the other direction.

17. The semiconductor device of claim 15, further comprising:
another source/drain pattern connected to the source/drain pattern through the channel pattern; and
a dummy source/drain pattern between the substrate and at least one among the source/drain pattern and the other source/drain pattern,
wherein the landing pad extends between the dummy source/drain pattern and the at least one the source/drain pattern, and
wherein the dummy source/drain pattern comprises a material having etching selectivity with respect to the landing pad.

18. The semiconductor device of claim 15, wherein the landing pad comprises silicon germanium, and
wherein a content (at %) of germanium of the landing pad is equal to or greater than 50 at % and smaller than 100 at %.

19. A semiconductor device comprising:
a substrate;
a channel pattern on the substrate extending in one direction;
a source/drain pattern contacting a side of the channel pattern, and comprising a first source/drain pattern and a second source/drain pattern on the first source/drain pattern;
a lower wire structure body on a bottom side of the substrate;
a through via penetrating the substrate and connected between the first source/drain pattern and the lower wire structure body; and
a landing pad, to which boron is doped, protruding toward a bottom side of the substrate from a bottom side of the first source/drain pattern,
wherein a width of the landing pad increases as a distance from the bottom side of the substrate increases.

20. The semiconductor device of claim 19, wherein the landing pad comprises silicon germanium, and
wherein a content (at %) of germanium of the landing pad is equal to or greater than 50 at % and smaller than 100 at %.
